(19) United States
(12) Patent Application Publication
(10) Pub. No.: US 2024/0234395 A9
(43) Pub. Date: Jul. 11, 2024

(54) ELECTRONIC DEVICE

(71) Applicant: InnoLux Corporation, Miao-Li County (TW)

(72) Inventors: Jia-Yuan CHEN, Miao-Li County (TW); Yu-Chia HUANG, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 18/369,837

(22) Filed: Sep. 18, 2023

(30) Foreign Application Priority Data
Oct. 24, 2022 (CN) 202211303777.6

(51) Int. Cl. H01L 25/16; G02F 1/13357; G02F 1/136; G02F 1/1368; G02F 1/157; G02F 1/163; G02F 1/16766; G02F 1/1677

(52) U.S. Cl. CPC H01L 25/167; G02F 1/133603; G02F 1/13613; G02F 1/13685; G02F 1/157; G02F 1/163; G02F 1/16766; G02F 1/1677; H01L 24/08

(57) ABSTRACT

A display device includes a substrate, at least one light emitting unit bound on the substrate, a transparency controllable unit disposed on the substrate, and an integrated circuit unit overlapped with the substrate. The integrated circuit unit includes a semiconducting structure and a conductive structure overlapped with the semiconducting structure. The integrated circuit unit is electrically connected to the at least one light emitting unit and the transparency controllable unit.

### BACKGROUND OF THE DISCLOSURE

### 1. Field of the Disclosure

The present disclosure relates to a display device, and more particularly to a transparency controllable electronic device.

### 2. Description of the Prior Art

Micro light emitting diodes can be applied to display devices to enhance the transparency of the display devices. However, electronic elements in the display device, such as driving elements, switching elements, and the like, may cause the decrease of transparency of the display device. In addition, when the display device has high transparency, the problem of low contrast of the images would occur, thereby affecting the display effect of the display device. Therefore, to improve the transparency of the display device, or to improve the contrast of images of the display device under the condition of improving the transparency, is one of the important issues in the present field.

### SUMMARY OF THE DISCLOSURE

The present disclosure aims at providing a display device.

In some embodiments, a display device is provided by the present disclosure. The display device includes a substrate, at least one light emitting unit bound on the substrate, a transparency controllable unit disposed on the substrate, and an integrated circuit unit overlapped with the substrate. The integrated circuit unit includes a semiconducting structure and a conductive structure overlapped with the semiconducting structure. The integrated circuit unit is electrically connected to the at least one light emitting unit and the transparency controllable unit.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a top view of an electronic device according to a first embodiment of the present disclosure.

FIG. 2 schematically illustrates a cross-sectional view of the electronic device according to the first embodiment of the present disclosure.

FIG. 3 schematically illustrates a cross-sectional view of an electronic device according to a second embodiment of the present disclosure.

FIG. 4 schematically illustrates a cross-sectional view of an electronic device according to a third embodiment of the present disclosure.

FIG. 5 schematically illustrates a cross-sectional view of an electronic device according to a fourth embodiment of the present disclosure.

FIG. 6 schematically illustrates a top view of an electronic device according to a fifth embodiment of the present disclosure.

FIG. 7 schematically illustrates a cross-sectional view of the electronic device according to the fifth embodiment of the present disclosure.

FIG. 8 schematically illustrates a cross-sectional view of an integrated circuit unit according to the fifth embodiment of the present disclosure.

FIG. 9 schematically illustrates a cross-sectional view of an electronic device according to a sixth embodiment of the present disclosure.

FIG. 10 schematically illustrates a cross-sectional view of an electronic device according to a seventh embodiment of the present disclosure.

FIG. 11 schematically illustrates a cross-sectional view of an electronic device according to an eighth embodiment of the present disclosure.

FIG. 12 schematically illustrates a top view of an electronic device according to a ninth embodiment of the present disclosure.

FIG. 13 schematically illustrates a controlling way of an integrated circuit unit according to an embodiment of the present disclosure.

FIG. 14 schematically illustrates a controlling way of an integrated circuit unit according to another embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the electronic device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

The electronic device of the present disclosure may include a display device, a sensing device, a back-light device, an antenna device, a tiled device or other suitable electronic devices, but not limited thereto. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may for example include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. It should be noted that the electronic device of the present disclosure may be combinations of the above-mentioned devices, but not limited thereto. The display device is taking as an example to describe the contents of the present disclosure in the following, but the present disclosure is not limited thereto.

It should be noted that the technical features in different embodiments described in the following can be replaced, recombined, or mixed with one another to constitute another embodiment without departing from the spirit of the present disclosure.

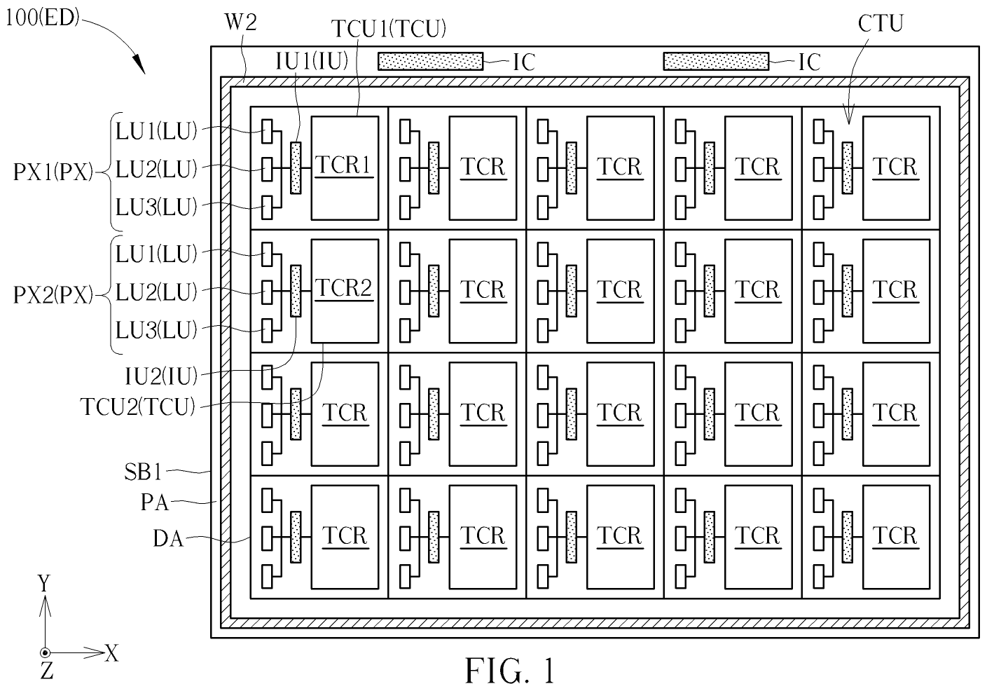

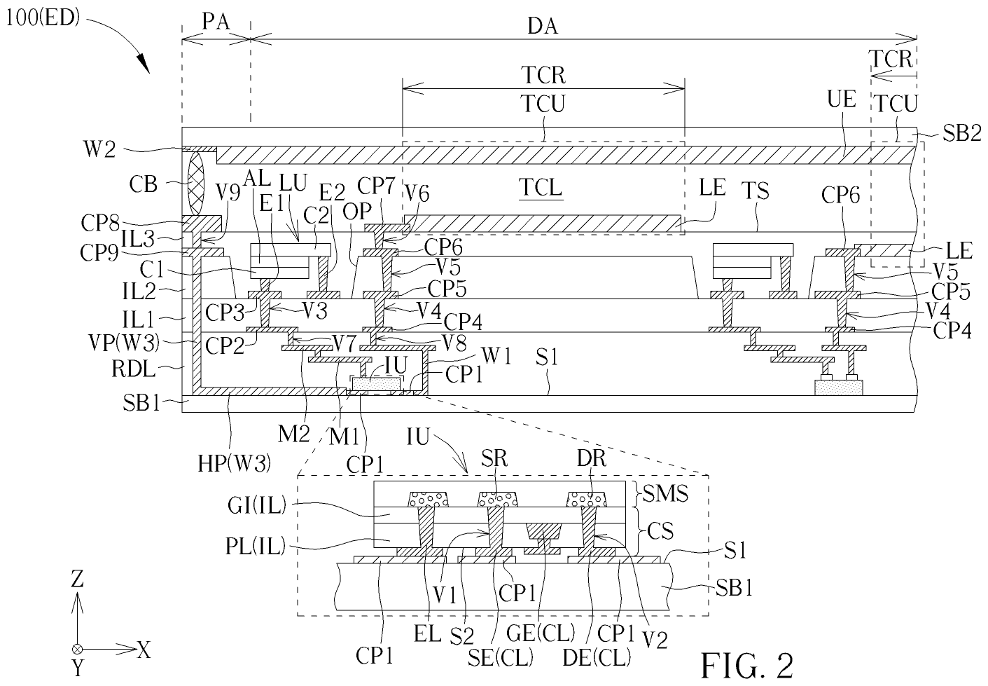

Referring to FIG. 1 and FIG. 2, FIG. 1 schematically illustrates a top view of an electronic device according to a first embodiment of the present disclosure, and FIG. 2 schematically illustrates a cross-sectional view of the electronic device according to the first embodiment of the present disclosure. According to the present disclosure, the electronic device ED shown in FIG. 1 and FIG. 2 may for example be a display device 100, or, the display device 100 may be applied to or included in the electronic device ED, wherein the display device 100 can display static or dynamic images or screens according to the user's demands and operations, but not limited thereto. The display device 100 may be a transparent display device or a display device with adjustable transparency. It should be noted that FIG. 1 just exemplarily shows the configuration of the elements of the display device 100 in a top view direction (for example, parallel to the direction Z) of the display device 100, and the detailed structures of the elements are not shown. As shown in FIG. 2, the display device 100 may include a substrate SB1, a light emitting unit LU, a transparency controllable unit TCU, and an integrated circuit unit IU, but not limited thereto. In the present embodiment, the light emitting unit LU, the integrated circuit unit IU and the transparency controllable unit TCU may be located on the substrate SB1, but not limited thereto. The elements and/or the layers included in the display device 100 will be detailed in the following.

The substrate SB1 may include any suitable supporting material for supporting the layers and/or the elements disposed thereon. In other words, the substrate SB1 can provide supporting function. It should be noted that the “substrate” mentioned in each of the embodiments of the present disclosure can be a layer having supporting function, which will not be redundantly described in the following. According to the present embodiment, the substrate SB1 may include a rigid substrate or a flexible substrate. The rigid substrate may for example include glass, quartz, sapphire, ceramic, other suitable materials or combinations of the above-mentioned materials, and the flexible substrate may for example include polyimide (PI) substrate, polycarbonate (PC) substrate, polyethylene terephthalate (PET) substrate, other suitable substrates or combinations of the above-mentioned substrates, but not limited thereto.

The light emitting unit LU may be used as a light source of the display device 100. According to the present embodiment, the light emitting unit LU may be bound on the substrate SB1, but not limited thereto. “The light emitting unit LU is bound on the substrate SB1” described herein may represent that the light emitting unit LU is formed at first, and then the light emitting unit LU can be transferred to the substrate SB1 through any suitable method, but not limited thereto. The definition of “bound” in the following may refer the contents mentioned above. In some embodiments, the light emitting unit LU may directly be formed on the substrate SB1. In detail, the display device 100 may include an insulating layer IL2 disposed on the substrate SB1, wherein the insulating layer IL2 may be patterned to form a plurality of openings OP therein, and the light emitting unit (s) LU may be located in the openings OP. The insulating layer IL2 may be regarded as the pixel defining layer, wherein the openings OP may be used to define the light emitting region of the display device 100, but not limited thereto. The insulating layer IL2 may include any suitable insulating material. The light emitting unit LU may for example include a light emitting diode, but not limited thereto. The light emitting diode may for example include an organic light emitting diode (OLED), a quantum light-emitting diode (QLED), an inorganic light emitting diode, other suitable light emitting elements or combinations of the above-mentioned elements. The inorganic light emitting diode may for example include a mini light emitting diode (mini LED) or a micro light emitting diode (micro LED), but not limited thereto. In some embodiments, the chip size of the light emitting diode may range from 300 micrometers (μm) to 10 millimeters (mm), the chip size of the mini light emitting diode may range from 100 micrometers to 300 micrometers, and the chip size of the micro light emitting diode may range from 1 micrometer to 100 micrometers, but not limited thereto. For example, in the present embodiment, the light emitting unit LU may include an inorganic light emitting diode (for example, a micro light emitting diode), thereby including a semiconductor layer C1, a semiconductor layer C2, an active layer AL located between the semiconductor layer C1 and the semiconductor layer C2, an electrode E1 connected to the semiconductor layer C1 and an electrode E2 connected to the semiconductor layer C2, but not limited thereto. In some embodiments, the light emitting unit LU may include other suitable light emitting materials.

As shown in FIG. 2, the display device 100 may further include an insulating layer IL3, wherein the insulating layer IL3 may be disposed on the insulating layer IL2 and filled into the openings OP, thereby covering the insulating layer IL2 and the light emitting unit LU to provide protection for the light emitting unit LU. The insulating layer IL3 may for example be an encapsulation layer to encapsulate the layers and the electronic elements (for example, the light emitting unit LU) between the insulating layer IL3 and the substrate SB1. In another aspect, the top surface TS of the insulating layer IL3 (or the surface of the insulating layer IL3 away from the light emitting unit LU) may for example be a flat surface, which helps to dispose other elements and/or layers on the insulating layer IL3.

The transparency controllable unit TCU of the present disclosure may include any element that the transparency thereof can be adjusted through any suitable way. In other words, the transparency of the transparency controllable unit TCU can be adjusted. The transparency controllable unit TCU may be disposed on the substrate SB1, but not limited thereto. “The transparency controllable unit TCU is disposed on the substrate SB1” described herein may include the embodiment that the transparency controllable unit TCU is formed on the substrate SB1 and the embodiment that the transparency controllable unit TCU is formed at first, and then the transparency controllable unit TCU is transferred to the substrate SB1 through any suitable way, but the present disclosure is not limited thereto.

As shown in FIG. 2, the transparency controllable unit TCU may include a top electrode UE, a bottom electrode LE and a transparency controllable layer TCL, wherein the transparency controllable layer TCL is located between the top electrode UE and the bottom electrode LE, but not limited thereto. Specifically, the transparency controllable unit TCU is composed of the top electrode UE, the bottom electrode LE and the transparency controllable layer TCL located between the top electrode UE and the bottom electrode LE. In the present embodiment, the top electrode UE and the transparency controllable layer TCL may for example be respectively disposed as a whole layer laterally extending above the disposition region of the transparency controllable unit TCU and the disposition region of the light emitting unit(s) LU, and the bottom electrode LE may be patterned (for example, the bottom electrode LE may correspond to the disposition region of the transparency controllable unit TCU, and the disposition region of the light emitting unit(s) LU may be exposed), but not limited thereto. In such condition, one of the transparency controllable units TCU may be composed of a portion of the top electrode UE, a portion of the bottom electrode LE corresponding to the portion of the top electrode UE, and a portion of the transparency controllable layer TCL between the portion of the top electrode UE and the portion of the bottom electrode LE, and the display device 100 may include a plurality of transparency controllable units TCU. In addition, the portions of the top electrode UE and the portions of the transparency controllable layer TCL not corresponding to the bottom electrode LE do not constitute a transparency controllable unit TCU. In some embodiments, the top electrode UE may be patterned to have a plurality of portions corresponding to the bottom electrode LE. “The top electrode UE corresponds to the bottom electrode LE” mentioned above may include the embodiment that the top electrode UE is at least partially overlapped with the bottom electrode LE in the top view direction of the display device 100.

As shown in the left part of FIG. 2, the bottom electrode LE may be disposed on the insulating layer IL3, the transparency controllable layer TCL may be disposed on the bottom electrode LE and the insulating layer IL3, and the top electrode UE may be disposed on the transparency controllable layer TCL, but not limited thereto. The top electrode UE and the bottom electrode LE may include any suitable conductive material, such as transparent conductive materials, but not limited thereto. The transparent conductive material may for example include indium tin oxide (ITO), indium zinc oxide (IZO), other suitable materials or combinations of the above-mentioned materials. The transparency controllable layer TCL may include any suitable material that the transparency or color thereof can be changed due to being affected by an electric field. For example, the material of the transparency controllable layer TCL may include dichroic dye liquid crystal (DDLC), polymer dispersed liquid crystal (PDLC), polymer network liquid crystal (PNLC), cholesteric liquid crystal (CLC), electrochromic (EC), suspended particle device (SPD), electronic ink or combinations of the above-mentioned materials, but not limited thereto. When an electrical field is generated due to a voltage difference between the top electrode UE and the bottom electrode LE, the material of the transparency controllable layer TCL can be affected by the electric field and change its transparency or color, thereby changing the transparency of the transparency controllable unit TCU. The structure of the transparency controllable unit TCU of the present embodiment is not limited to the above-mentioned structure, and may include any suitable structure according to the demands of the design of the product.

It should be noted that the disposition position of the top electrode UE, the bottom electrode LE and/or the transparency controllable layer TCL of the transparency controllable unit TCU is not limited to the above-mentioned contents. In some embodiments, as shown in the right part of FIG. 2, the bottom electrode LE may be disposed on the insulating layer IL2, and the insulating layer IL3 may cover the bottom electrode LE, but not limited thereto. In some embodiments, according to the demands of the design of the product, the top electrode UE and/or the bottom electrode LE may be disposed at any suitable position in the display device 100, and the transparency controllable layer TCL may be disposed at any suitable position between the top electrode UE and the bottom electrode LE.

As shown in FIG. 1 and FIG. 2, the display device 100 may have at least one transparency controllable region TCR, wherein the transparency controllable region TCR may be defined by the disposition position of the transparency controllable unit TCU. Specifically, the region enclosed by the outer edge of the transparency controllable unit TCU may be defined as the transparency controllable region TCR, but not limited thereto. The transparency of the transparency controllable region TCR of the display device 100 is adjustable. Since the display device 100 of the present embodiment may include a plurality of transparency controllable units TCU, the display device 100 may have a plurality of transparency controllable regions TCR, but not limited thereto. It should be noted that the shape and the size of the transparency controllable region TCR shown in FIG. 1 are just exemplary, and the present disclosure is not limited thereto. The shape and the size of the transparency controllable region TCR may be determined according to the structures of the top electrode UE, the bottom electrode LE and/or the transparency controllable layer TCL.

According to the present embodiment, the transparency controllable unit TCU may not be disposed corresponding to the light emitting unit (s) LU, that is, in the top view direction of the display device 100, the transparency controllable unit TCU is not overlapped with the light emitting unit(s) LU, but not limited thereto. “The transparency controllable unit TCU is not corresponding to the light emitting unit (s) LU” described herein may for example represent that the transparency controllable unit TCU is not overlapped with the light emitting layer(s) (for example, the active layer(s) AL) of the light emitting unit (s) LU, but not limited thereto. For example, as shown in FIG. 2, the bottom electrode LE disposed on the insulating layer IL3 may be patterned to expose the light emitting unit (s) LU, for example, the bottom electrode LE may be formed by removing a portion of a conductive material layer corresponding to the light emitting unit(s) LU, but not limited thereto. Since the bottom electrode LE may not correspond to the light emitting unit(s) LU, the transparency controllable unit TCU composed of the bottom electrode LE, the top electrode UE and the transparency controllable layer TCL may not correspond to the light emitting unit(s) LU. It should be noted that the transparency controllable layer TCL can be not corresponding to the light emitting unit (s) LU through other ways. In some embodiments, a portion of the top electrode UE corresponding to the light emitting unit (s) LU may be removed. In some embodiments, a portion of the transparency controllable layer TCL corresponding to the light emitting unit(s) LU may be removed. As shown in FIG. 1, since the transparency controllable unit TCU may not be disposed corresponding to the light emitting unit(s) LU, the transparency controllable region TCR may not overlap the light emitting unit(s) LU in the top view direction of the display device 100 (or on the X-Y plane perpendicular to the normal line of the display device 100). By making the transparency controllable unit TCU not disposed corresponding to the light emitting unit(s) LU, the influence of the transparency controllable unit TCU on the display effect of the display device 100 may be reduced, thereby improving the performance of the display device 100.

According to the present embodiment, the integrated circuit unit IU may be bound on the substrate SB1, and the integrated circuit unit IU may overlap the substrate SB1. In detail, the integrated circuit unit IU may be bound on the top surface S1 of the substrate SB1, wherein the top surface S1 of the substrate SB1 may be the surface of the substrate SB1 facing the light emitting unit(s) LU and/or the transparency controllable unit TCU. In addition, in the top view direction of the display device 100, the integrated circuit unit IU may be located under the light emitting unit(s) LU and the transparency controllable unit TCU, but not limited thereto. The integrated circuit unit IU may for example include a chip, but not limited thereto. In other words, the display device 100 may include a chip bound on the substrate SB1. Specifically, the chip of the integrated circuit unit IU may be formed at first, and then the chip of the integrated circuit unit IU may be transferred to the substrate SB1 and bound on the top surface S1 of the substrate SB1.

FIG. 2 shows the structure of the integrated circuit unit IU of the present embodiment. As shown in the lower part of FIG. 2, the integrated circuit unit IU may include at least one transistor which includes a source region SR, a drain region DR, a source electrode SE electrically connected to the source region SR, a drain electrode DE electrically connected to the drain region DR and a gate electrode GE, but not limited thereto. In addition, the integrated circuit unit IU may further include a gate insulating layer GI disposed between the gate electrode GE and the source region SR and/or the drain region DR and an insulating layer PL disposed at a side of the gate insulating layer GI, wherein the insulating layer PL is at the side of the gate insulating layer GI where the gate electrode GE is disposed and may cover the gate electrode GE, but not limited thereto. The source electrode SE may extend on the surface S2 of the integrated circuit unit IU and be filled into the via V1 penetrating through the gate insulating layer GI and the insulating layer PL to be electrically connected to the source region SR; the drain electrode DE may extend on the surface S2 of the integrated circuit unit IU and be filled into the via V2 penetrating through the gate insulating layer GI and the insulating layer PL to be electrically connected to the drain region DR. The surface S2 of the integrated circuit unit IU may be the surface of the integrated circuit unit IU away from the source region SR and/or the drain region DR, such as the surface of the insulating layer PL, but not limited thereto. The source electrode SE, the drain electrode DE and the gate electrode GE may include any suitable conductive material, such as metal materials, but not limited thereto. The gate insulating layer GI and the insulating layer PL may include any suitable insulating material. It should be noted that the structure of the integrated circuit unit IU shown in FIG. 2 is just exemplary, and the present embodiment is not limited thereto.

According to the present embodiment, the integrated circuit unit IU may include a semiconducting structure SMS and a conductive structure CS, wherein the conductive structure CS may overlap the semiconducting structure SMS. Specifically, the integrated circuit unit IU may include a structure formed by stacking the semiconducting structure SMS and the conductive structure CS. The semiconducting structure SMS may be defined as the portion or region of the integrated circuit unit IU including semiconductor material. The semiconductor material may for example include silicon carbide (SiC), silicon (Si), germanium (Ge), gallium arsenide (GaAs), indium phosphide (InP), gallium nitride (GaN), other suitable materials or combinations of the above-mentioned materials. The semiconductor material may for example include low temperature polysilicon (LTPS), low temperature polysilicon oxide (LTPO), or amorphous silicon (a-Si), but not limited thereto. The semiconductor material may include (but not limited to) amorphous silicon, polysilicon, germanium, compound semiconductor (such as gallium nitride, silicon carbide, gallium arsenide, gallium phosphide, indium phosphide, indium arsenide and/or indium antimonide), alloy semiconductor (such as silicon-germanium (SiGe) alloy, gallium-arsenic-phosphorus (GaAsP) alloy, aluminum-indium-arsenic (AlInAs)alloy, aluminum-gallium-arsenic (AlGaAs) alloy, gallium-indium-arsenic (GaInAs) alloy, gallium-indium-phosphorus (GaInP) alloy or gallium-indium-arsenic-phosphorus (GaInAsP) alloy), or combinations of the above-mentioned materials. The semiconductor material may include (but not limited to) metal oxides (such as indium gallium zinc oxide (IGZO), indium zinc oxide (IZO) or indium gallium zinc tin oxide (IGZTO)), organic semiconductors having polycyclic aromatic compounds, or combinations of the above-mentioned materials. In the present embodiment, the source region SR and the drain region DR of the integrated circuit unit IU may be formed by doping a portion of the region of the semiconducting structure SMS including semiconductor materials, and the non-doped region of the semiconducting structure SMS between the source region SR and the drain region DR may be regarded as the channel region or the active region of the transistor. The conductive structure CS may include a conductive layer CL and at least one insulating layer IL, wherein the insulating layer IL may be disposed between the semiconducting structure SMS and the conductive layer CL, but not limited thereto. Specifically, the conductive layer CL may include the conductive elements of the integrated circuit unit IU, such as the source electrode SE, the drain electrode DE and gate electrode GE mentioned above, and the insulating layer IL may for example include the gate insulating layer GI and insulating layer PL mentioned above, wherein the gate insulating layer GI and the insulating layer PL may be disposed between the semiconducting structure SMS and the source electrode SE, the drain electrode DE and/or the gate electrode GE, but not limited thereto. In other words, in the integrated circuit unit IU, the portion of the integrated circuit unit IU including the semiconductor materials (such as the source region SR, the drain region DR and the active region) may be defined as the semiconducting structure SMS, and the portion of the integrated circuit unit IU including conductive elements (such as the source electrode SE, the drain electrode DE and the gate electrode GE) and insulating layers (such as the gate insulating layer GI and the insulating layer PL) may be defined as the conductive structure CS. In some embodiments, the conductive structure CS may further include other suitable insulating layers and/or conductive layers.

The integrated circuit unit IU of the present embodiment may be disposed on the substrate SB1 in a flip chip way, that is, the integrated circuit unit IU is bound on the substrate SB1 in the way that the conductive structure CS of the integrated circuit unit IU faces the top surface S1 of the substrate SB1, but not limited thereto. Therefore, the surface S2 of the integrated circuit unit IU faces the top surface S1 of the substrate SB1. A plurality of conductive pads CP1 may be disposed on the top surface S1 of the substrate SB1, and the source electrode SE, the drain electrode DE and/or the gate electrode GE extending on the surface S2 in the integrated circuit unit IU may be electrically connected to the conductive pads CP1, such that the integrated circuit unit IU can be bound on the substrate SB1. In such condition, the conductive layer CL of the conductive structure CS, the insulating layer IL of the conductive structure CS, and the semiconducting structure SMS in the integrated circuit unit IU are sequentially located on the substrate SB1 from bottom to top. In other words, the conductive layer CL may be disposed between the substrate SB1 and the insulating layer IL, and the insulating layer IL may be disposed between the conductive layer CL and the semiconducting structure SMS. It should be noted that the binding method of the integrated circuit unit IU of the present disclosure is not limited to the above-mentioned contents, and any suitable binding method can be applied to the integrated circuit unit IU according to the demands of the design of the product.

According to the present embodiment, the integrated circuit unit IU may be electrically connected to at least one light emitting unit LU and the transparency controllable unit TCU, so as to control the light emission of the light emitting unit LU and the transparency of the transparency controllable unit TCU. Specifically, the integrated circuit unit IU may be electrically connected to the bottom electrode LE of the transparency controllable unit TCU, and the voltage difference between the bottom electrode LE and the top electrode UE may be changed by providing an electrical signal to adjust the transparency of the transparency controllable unit TCU, but not limited thereto. In detail, the display device 100 may further include a redistribution layer RDL disposed on the substrate SB1, a conductive pad CP2 disposed on the redistribution layer RDL, an insulating layer IL1 disposed on the redistribution layer RDL and covering the conductive pad CP2, and a conductive pad CP3 disposed on the insulating layer IL1, but not limited thereto. The insulating layer IL1 may include any suitable insulating material. The integrated circuit unit IU may be electrically connected to the conductive pad CP2 through the redistribution layer RDL. The insulating layer IL1 may have a via V3 corresponding to the conductive pad CP3, and the conductive pad CP3 may be filled into the via V3 and contacts the conductive pad CP2, such that the conductive pad CP3 may be electrically connected to the conductive pad CP2. The electrode (such as the electrode E1 shown in FIG. 2) of the light emitting unit LU may be electrically connected to the conductive pad CP3. Therefore, the integrated circuit unit IU may be electrically connected to the light emitting unit LU through the redistribution layer RDL, the conductive pad CP2 and the conductive pad CP3, thereby controlling the light emission of the light emitting unit LU. In addition, the display device 100 of the present embodiment may further include a conductive pad CP4 disposed on the redistribution layer RDL, a conductive pad CP5 disposed on the insulating layer IL1, a conductive pad CP6 disposed on the insulating layer IL2, and a conductive pad CP7 disposed on the insulating layer IL3, but not limited thereto. The integrated circuit unit IU may be electrically connected to the conductive pad CP4 through the redistribution layer RDL. The insulating layer IL1 may include a via V4 corresponding to the conductive pad CP4, and the conductive pad CP5 may be filled into the via V4 and contacts the conductive pad CP4, such that the conductive pad CP5 may be electrically connected to the conductive pad CP4. Similarly, the conductive pad CP6 may be electrically connected to the conductive pad CP5 through a via V5, and the conductive pad CP7 may be electrically connected to the conductive pad CP6 through a via V6. The conductive pad CP7 may be electrically connected to the electrode of the transparency controllable unit TCU, such as the bottom electrode LE, but not limited thereto. Therefore, the integrated circuit unit IU may be electrically connected to the transparency controllable unit TCU through the redistribution layer RDL, the conductive pad CP4, the conductive pad CP5, the conductive pad CP6 and the conductive pad CP7, so as to control the transparency of the transparency controllable unit TCU. In some embodiments, when the bottom electrode LE of the transparency controllable unit TCU is disposed under the insulating layer IL3 (as shown in the right part of FIG. 2), the display device 100 may not include the conductive pad CP7, and the conductive pad CP6 may be electrically connected to the bottom electrode LE. The above-mentioned conductive pads may include any suitable conductive material, such as metal materials, but not limited thereto. In the present embodiment, the conductive pad CP2 and the conductive pad CP4 may be formed of the same conductive layer, and the conductive pad CP3 and the conductive pad CP5 may be formed of the same conductive layer, but not limited thereto. It should be noted that the layout design of the display device 100 of the present embodiment is not limited to the above-mentioned contents. In some embodiments, the display device 100 may include any suitable layout design according to the demands of the design of the product, such that the integrated circuit unit IU may be electrically connected to the light emitting unit LU and the transparency controllable unit TCU.

The redistribution layer RDL may include any suitable layer that can adjust the positions of the signal input terminal and the signal output terminal or adjust the layout of the wires. For example, the signal input terminal and the signal output terminal respectively located at two sides of the redistribution layer RDL may not correspond to each other, but not limited thereto. For example, when the integrated circuit unit IU is electrically connected to the light emitting unit LU through the redistribution layer RDL, the position of the signal input terminal may be located at the via V2 of the drain electrode DE of the integrated circuit unit IU, and the position of the signal output terminal may for example be located at the via V7 corresponding to the conductive pad CP2, wherein the position of the via V2 may not correspond to the position of the via V7, but not limited thereto. Similarly, when the integrated circuit unit IU is electrically connected to the transparency controllable unit TCU through the redistribution layer RDL, the position of the via V2 may not correspond to the position of the via V8 corresponding to the conductive pad CP4. The redistribution layer RDL of the present embodiment may for example include a structure formed by alternately stacking a plurality of insulating layers (not shown) and a plurality of conductive layers (such as the conductive layer M1 and the conductive layer M2, but not limited thereto), but not limited thereto. The layout of the wires in the redistribution layer RDL may be determined through the disposition positions of the conductive layers (such as the conductive layer M1 and the conductive layer M2). In addition, the insulating layer(s) of the redistribution layer RDL may include via, such that the wires can be transferred to another layer in the redistribution layer RDL. The conductive layers of the redistribution layer RDL may include any suitable conductive material, such as metal materials, but not limited thereto. The insulating layers of the redistribution layer RDL may include any suitable insulating material, such as polyimide, but not limited thereto. According to the present embodiment, since the integrated circuit unit IU of the display device 100 may include a chip and may have a smaller size, the difficulty of electrical connection between the integrated circuit unit IU and the light emitting unit LU and/or the transparency controllable unit TCU may be reduced through the redistribution layer RDL, thereby improving the performance or spatial configuration of the display device.

It should be noted that FIG. 2 just exemplarily shows the condition that the integrated circuit unit IU is electrically connected to the redistribution layer RDL, which does not show the actual structure of the display device 100. As shown in FIG. 2, the integrated circuit unit IU of the present embodiment may be bound on the substrate SB1 in a flip chip way, wherein the source electrode SE, the drain electrode DE and/or the gate electrode GE of the integrated circuit unit IU may be electrically connected to the conductive pads CP1 on the substrate SB1. In the present embodiment, the display device 100 may further include a wire W1 electrically connected to the conductive pad CP1, wherein the wire W1 may be electrically connected between the electrode of the integrated circuit unit IU (such as the drain electrode DE, but not limited thereto) and the conductive layer of the redistribution layer RDL, such that the integrated circuit unit IU is electrically connected to the redistribution layer RDL. In other words, the integrated circuit unit IU of the present embodiment may be electrically connected to the redistribution layer RDL through the conductive pads CP1 and the wire W1. In some embodiments, the integrated circuit unit IU may be electrically connected to the redistribution layer RDL through other suitable ways.

According to the present embodiment, the integrated circuit unit IU may not be disposed corresponding to the transparency controllable unit TCU. In other words, in the top view direction of the display device 100, the integrated circuit unit IU may not overlap the transparency controllable unit TCU. By making the integrated circuit unit IU not disposed corresponding to the transparency controllable unit TCU, the influence of the integrated circuit unit IU on the transparency of the transparency controllable unit TCU may be reduced, thereby improving the performance of the display device 100. In addition, in the present embodiment, the integrated circuit unit IU may not overlap the light emitting unit (s) LU in the top view direction of the display device 100, but not limited thereto. In some embodiments, the integrated circuit unit IU may overlap at least one light emitting unit LU in a top view direction of the display device 100.

As shown in FIG. 1, in the present embodiment, the display device 100 may include a plurality of integrated circuit units IU, wherein one of the integrated circuit units IU may be electrically connected to at least three light emitting units LU and one transparency controllable unit TCU, but not limited thereto. In detail, the display device 100 may include a light emitting unit LU1, a light emitting unit LU2, a light emitting unit LU3, an integrated circuit unit IU1, and a transparency controllable unit TCU1, wherein the integrated circuit unit IU1 may be electrically connected to the light emitting unit LU1, the light emitting unit LU2 and the light emitting unit LU3 to control the light emission of the light emitting unit LU1, the light emitting unit LU2 and the light emitting unit LU3. In addition, the integrated circuit unit IU1 may be electrically connected to the transparency controllable unit TCU1 to control the transparency of the transparency controllable unit TCU1. A transparency controllable region TCR1 may be defined by the transparency controllable unit TCU1. In the present embodiment, the light emitting unit LU1, the light emitting unit LU2 and the light emitting unit LU3 may for example constitute a pixel PX, such as the pixel PX1, but not limited thereto. In other words, the light emitting units LU in the same pixel PX may be electrically connected to the same integrated circuit unit IU and controlled by the same integrated circuit unit IU. In some embodiments, the light emitting unit LU1, the light emitting unit LU2 and the light emitting unit LU3 may respectively emit lights of different colors, such as red light, blue light and green light, but not limited thereto. In some embodiments, the light emitting unit LU1, the light emitting unit LU2 and the light emitting unit LU3 may emit lights of the same color. In some embodiments, when more than three light emitting units LU are included in one pixel PX, the integrated circuit unit IU may be electrically connected to more than three light emitting units LU. In addition, in the present embodiment, the transparency controllable unit TCU1 electrically connected to the integrated circuit unit IU1 may for example be adjacent to the pixel PX1, or adjacent to the light emitting unit LU1, the light emitting unit LU2 and the light emitting unit LU3 in the pixel PX1, but not limited thereto. In other words, the integrated circuit unit IU may be electrically connected to the light emitting units LU in a pixel PX and the transparency controllable unit TCU adjacent to the pixel PX. For example, the display device 100 may further include a pixel PX2 composed of the light emitting unit LU1, the light emitting unit LU2 and the light emitting unit LU3, an integrated circuit unit IU2, and a transparency controllable unit TCU2 (or a transparency controllable region TCR2) adjacent to the pixel PX2, wherein the integrated circuit unit IU2 may be electrically connected to the light emitting unit LU1, the light emitting unit LU2 and the light emitting unit LU3 in the pixel PX2 and the transparency controllable unit TCU2, but not limited thereto. According to the present embodiment, when the integrated circuit unit IU controls a light emitting unit LU to emit lights or display images, the integrated circuit unit IU may be used to control the transparency of the transparency controllable unit TCU adjacent to the light emitting unit LU (for example, reduce the transparency of the transparency controllable unit TCU), such that the contrast of the images displayed by the light emitting unit LU may be increased, but not limited thereto. Therefore, the display effect of the display device 100 may be improved.

It should be noted that the electrical connection between the integrated circuit unit IU and the light emitting unit LU (or the transparency controllable unit TCU) is not limited to the above-mentioned contents. In some embodiments, an integrated circuit unit IU may be electrically connected to a light emitting unit LU and a transparency controllable unit TCU adjacent to the light emitting unit LU. In some embodiments, an integrated circuit unit IU may be electrically connected to a light emitting unit LU and the plurality of transparency controllable units TCU adjacent to the light emitting unit LU. In some embodiments, a light emitting unit LU and the transparency controllable unit TCU adjacent to the light emitting unit LU may be electrically connected to different integrated circuit units IU.

As shown in FIG. 1, the display device 100 of the present embodiment may include an active area DA and a peripheral area PA. The active area DA may be the area of the display device 100 including the light emitting unit(s) LU, and the active area DA may be used for displaying images. In other words, the active area DA may be regarded as the display area of the display device 100. The active area DA of the present embodiment may for example be defined by the light emitting unit (s) LU of the display device 100, but not limited thereto. Specifically, the active area DA may for example be defined as the area enclosed by the outer edges of the outermost light emitting units LU among the light emitting units LU, and the area other than the active area DA may be defined as the peripheral area PA, but not limited thereto. In the present embodiment, the light emitting unit LU, the integrated circuit unit IU and the transparency controllable unit TCU may for example be located in the active area DA, but not limited thereto. In the present embodiment, an integrated circuit unit IU, the pixel PX electrically connected to the integrated circuit unit IU, and the transparency controllable unit TCU (or the transparency controllable region TCR) electrically connected to the integrated circuit unit IU may form a complex unit CTU, and the complex unit CTU may be arranged in the active area DA in an array.

As shown in FIG. 1 and FIG. 2, according to the present embodiment, the display device 100 may further include a wire W2, a conductive material CB, a conductive pad CP8, a conductive pad CP9, and a wire W3, but not limited thereto. The wire W2 may be disposed in the peripheral area PA of the display device 100 and may be electrically connected to the top electrode UE of the transparency controllable unit TCU. In addition, in the top view direction of the display device 100, the wire W2 may include a ring shape and surround the light emitting unit LU, the integrated circuit unit IU and the transparency controllable unit TCU, but not limited thereto. For example, the wire W2 may be disposed along the sides of the top electrode UE and surround the top electrode UE, but not limited thereto. The wire W2 may include any suitable conductive material. The conductive material CB may be disposed in the peripheral area PA of the display device 100, and the conductive material CB may be disposed between the wire W2 and the conductive pad CP8, but not limited thereto. In other words, the conductive material CB may be electrically connected between the wire W2 and the conductive pad CP8. The conductive material CB may for example include metal materials, such as gold (Au), but not limited thereto. The conductive pad CP8 and the conductive pad CP9 may be disposed in the peripheral area PA of the display device 100, wherein the conductive pad CP8 may be disposed on the insulating layer IL3, and the conductive pad CP9 may be disposed between the insulating layer IL2 and the insulating layer IL3, but not limited thereto. The conductive pad CP8 and the conductive pad CP9 may include any suitable conductive material. The insulating layer IL3 may include a via V9 corresponding to the conductive pad CP8, and the conductive pad CP8 may be filled into the via V9 and contact the conductive pad CP9, such that the conductive pad CP8 may be electrically connected to the conductive pad CP9. The wire W3 may be electrically connected to the conductive pad CP9. The wire W3 may include a first portion VP penetrating through the insulating layer IL2, the insulating layer IL1, and the redistribution layer RDL, and a second portion HP extending on the top surface S1 of the substrate SB1. The first portion VP may be located in the peripheral area PA. The first portion VP may be formed of multiple transferred wires, but not limited thereto. The second portion HP may for example extend from the peripheral area PA to the active area DA and be electrically connected to the integrated circuit unit IU. For example, as shown in the lower part of FIG. 2, the integrated circuit unit IU may further include an electrode EL, wherein the electrode EL may extend on the surface S2 of the integrated circuit unit IU and be filled into a via penetrating the gate insulating layer GI and the insulating layer PL to be electrically connected to the semiconducting structure SMS, wherein the electrode EL may be electrically connected to the conductive pad CP1 on the top surface S1 of the substrate SB1, and the second portion HP of the wire W3 may be electrically connected to the conductive pad CP1 to which the electrode EL is electrically connected, such that the second portion HP may be electrically connected to the integrated circuit unit IU, but not limited thereto. The wire W3 may include any suitable conductive material. Therefore, the top electrode UE of the transparency controllable unit TCU may be electrically connected to the electrode EL of the integrated circuit unit IU through the wire W2, the conductive material CB, the conductive pad CP8, the conductive pad CP9, the wire W3 and the conductive pad CP1, such that the top electrode UE may be electrically connected to the integrated circuit unit IU, but not limited thereto. In some embodiments, the top electrode UE of the transparency controllable unit TCU may be electrically connected to the integrated circuit unit IU through other ways. By making the conductive structure for electrical connecting the top electrode UE and the integrated circuit unit IU disposed in the peripheral area PA, the flexibility of spatial configuration of the active area DA of the display device 100 may be improved.

Since the top electrode UE of the transparency controllable unit TCU may be electrically connected to the integrated circuit unit IU, a common voltage may be provided to the top electrode UE through the integrated circuit unit IU. In other words, the top electrode UE may be regarded as the common electrode of different transparency controllable units TCU, but not limited thereto. In some other embodiments, the integrated circuit unit IU may provide a common voltage to the bottom electrode LE of the transparency controllable unit TCU and provide an electrical signal that can change the transparency of the transparency controllable unit TCU to the top electrode UE. That is, the bottom electrode LE may be regarded as the common electrode of different transparency controllable units TCU.

In the present embodiment, the integrated circuit unit IU to which the top electrode UE is electrically connected may for example be the outermost integrated circuit unit IU in the display device 100, but not limited thereto. In other words, the second portion HP of the wire W3 may extend from the peripheral area PA to the active area DA and contact the outermost integrated circuit unit IU, such that the space in the active area DA occupied by the wire W3 may be reduced, thereby improving the flexibility of spatial configuration of the active area DA or improving the display effect of the display device 100. In addition, the top electrode UE of the present embodiment may for example be electrically connected to more than one integrated circuit units IU. Specifically, the display device 100 may include a plurality of conductive materials CB, a plurality of conductive pads CP8, a plurality of conductive pads CP9 and a plurality of wires W3 electrically connected to the wire W2, thereby including a plurality of second portions HP of the wires W3, wherein the plurality of second portions HP may extend from the peripheral area PA to the active area DA and be electrically connected to one of the outermost integrated circuit units IU respectively, but not limited thereto. In some embodiments, a wiring structure electrically connected to the wire W2 may be disposed in the active area DA to improve the uniformity of the electric field, thereby improving the contrast uniformity of the transparency controllable region TCR. In some embodiments, each of the outermost integrated circuit units IU may be electrically connected to a wire W3. Through the above-mentioned design, the stability of the common voltage provided by the integrated circuit unit IU may be improved, thereby improving the performance of the transparency controllable unit TCU.

In some embodiments, as shown in FIG. 1, the display device 100 may further include peripheral electronic elements IC, wherein the peripheral electronic elements IC may be disposed in the peripheral area PA, but not limited thereto. The peripheral electronic element IC may be electrically connected to the integrated circuit unit IU, such that electrical signals can be transmitted between the integrated circuit unit IU and the peripheral electronic element IC. For example, the integrated circuit unit IU may be electrically connected to the peripheral electronic element IC through the redistribution layer RDL, but not limited thereto. The peripheral electronic element IC may further be electrically connected to other suitable electronic elements of the display device 100. The peripheral electronic element IC may for example include chip, flexible printed circuit board (FPCB), other suitable electronic elements or combinations of the above-mentioned elements, but not limited thereto.

In some embodiments, as shown in FIG. 2, the display device 100 may further include a substrate SB2, wherein the substrate SB2 may be disposed on the transparency controllable unit TCU. In other words, the light emitting unit LU, the transparency controllable unit TCU and the integrated circuit unit IU may be disposed between the substrate SB1 and the substrate SB2, but not limited thereto. The material of the second substrate SB2 may refer to the material of the substrate SB1 mentioned above, and will not be redundantly described. The material of the substrate SB2 and the material of the substrate SB1 may be the same or different, and the present disclosure is not limited thereto.

As mentioned above, the display device 100 may include the light emitting unit LU, the transparency controllable unit TCU and the integrated circuit unit IU, wherein the integrated circuit unit IU may for example be a chip bound on the substrate SB1. In addition, the integrated circuit unit IU may be electrically connected to the light emitting unit LU and the transparency controllable unit TCU to control the light emitting unit LU and the transparency controllable unit TCU. In other words, the integrated circuit unit IU may be the driving unit of the light emitting unit LU and the transparency controllable unit TCU. According to the present embodiment, since the size of the integrated circuit unit IU (such as a chip) may be smaller than the size of the driving element (such as a thin film transistor) in a conventional display device, the transparency of the display device 100 may be increased, thereby improving the display effect of the display device 100. In addition, in the present embodiment, the integrated circuit unit IU may control the light emitting unit LU and the transparency controllable unit TCU adjacent to that light emitting unit LU. Therefore, when the integrated circuit unit IU controls the light emitting unit LU to emit light and display images, the transparency of the transparency controllable unit TCU adjacent to that light emitting unit LU may be reduced through the integrated circuit unit IU, thereby increasing the contrast of the image displayed by the light emitting unit LU, such that the display effect of the display device may be improved. Therefore, the display effect of the display device 100 may be improved under the condition that the transparency of the display device 100 is increased.

It should be noted that the elements and/or the layers included in the display device 100 of the present embodiment is not limited to the above-mentioned contents, and the display device 100 may further include any suitable element and/or layer that can be applied to the display device 100. Other embodiments of the present disclosure will be described in the following. In order to simplify the description, the same elements or layers in the following embodiments would be labeled with the same symbol, and the features thereof will not be redundantly described. The differences between the embodiments will be detailed in the following.

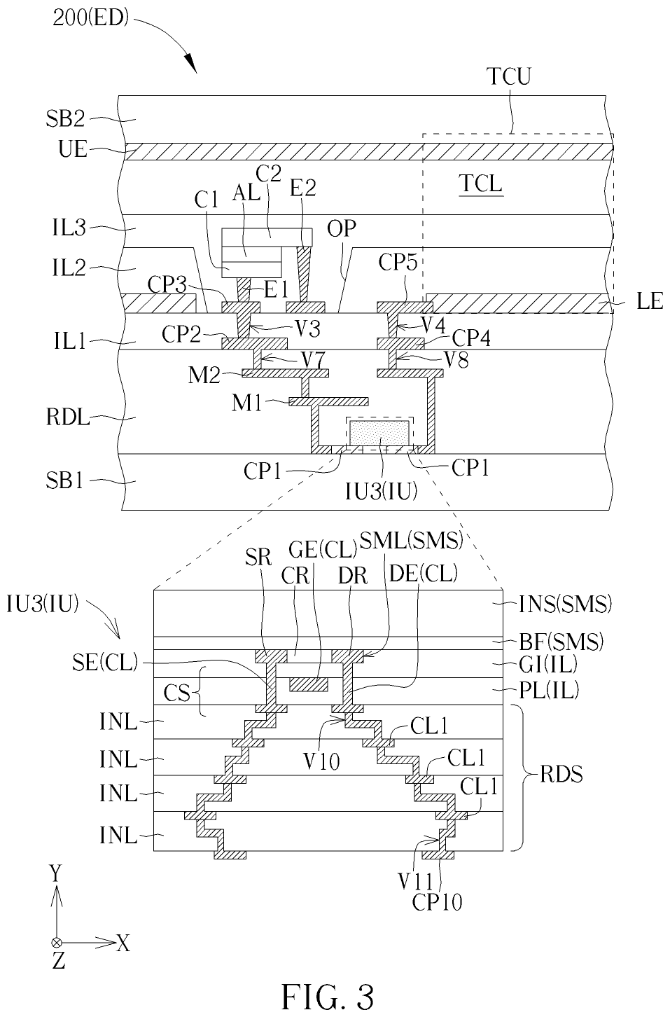

Referring to FIG. 3, FIG. 3 schematically illustrates a cross-sectional view of an electronic device according to a second embodiment of the present disclosure. In the present embodiment, the bottom electrode LE of the transparency controllable unit TCU of the display device 200 may be disposed between the insulating layer IL1 and the insulating layer IL2, wherein the insulating layer IL2 may cover the bottom electrode LE, but not limited thereto. The conductive pad CP5 may be directly electrically connected to the bottom electrode LE and electrically connected to the conductive pad CP4 through the via V4, and the conductive pad CP4 may be electrically connected to the integrated circuit unit IU through the redistribution layer RDL, thereby electrically connecting the integrated circuit unit IU to the bottom electrode LE.

The display device 200 of the present embodiment may include the integrated circuit unit IU3 bound on the substrate SB1, wherein the transistor in the integrated circuit unit IU3 may be the thin film transistor. For example, the integrated circuit unit IU3 may include the semiconducting structure SMS, the conductive structure CS and the redistribution structure RDS, and the conductive structure CS may be disposed between the semiconducting structure SMS and the redistribution structure RDS. The semiconducting structure SMS may include an insulating substrate INS and a semiconductor layer SML, wherein the semiconductor layer SML may be disposed on a surface of the insulating substrate INS. The insulating substrate INS may include any insulating material that can provide a support function. For example, the insulating substrate INS may include a glass substrate, but not limited thereto. The semiconductor layer SML may include a source region SR, a drain region DR and a channel region CR between the source region SR and the drain region DR. The conductive structure CS may include conductive layers CL and insulating layers IL, wherein the conductive layers CL may for example include a source electrode SE electrically connected to the source region SR, a drain electrode DE electrically connected to the drain region DR and a gate electrode GE disposed corresponding to the channel region CR, and the insulating layers IL may include a gate insulating layer GI and an insulating layer PL, but not limited thereto. The semiconductor layer SML may be disposed between the insulating substrate INS and the insulating layers IL, and the insulating layers IL may be disposed between the semiconductor layer SML and the conductive layers CL. The semiconductor layer SML, the source electrode SE, the drain electrode DE, the gate electrode GE and the gate insulating layer GI may constitute the thin film transistor element in the integrated circuit unit IU3. In addition, the semiconducting structure SMS may optionally include a buffer layer BF disposed between the insulating substrate INS and the semiconductor layer SML.

The redistribution structure RDS may include a structure formed by alternately stacking a plurality of insulating layers INL and a plurality of conductive layers (such as the conductive layers CL1, but not limited thereto), wherein the insulating layer INL may include at least one via, such that the conductive layers CL1 can be electrically connected to each other to form a wire, but not limited thereto. The conductive layer CL (such as the drain electrode DE) of the conductive structure CS of the integrated circuit unit IU3 may be introduced to a conductive pad CP10 disposed on a surface of the redistribution structure RDS opposite to the conductive structure CS by being electrically connected to the redistribution structure RDS (or the conductive layers CL1 in the redistribution structure RDS), and the conductive pad CP10 may be electrically connected to the light emitting unit LU and the transparency controllable unit TCU. For example, after the integrated circuit unit IU3 is bound on the substrate SB1, the conductive pad CP10 may be electrically connected to the conductive pad CP1 shown in FIG. 2, thereby being electrically connected to the light emitting unit LU and the transparency controllable unit TCU, but not limited thereto. The light emitting unit LU and the transparency controllable unit TCU may be electrically connected to the conductive structure CS through the redistribution structure RDS in the integrated circuit unit IU3. The redistribution structure RDS may have the function of adjusting the positions of the signal input terminal and the signal output terminal or adjusting the layout of the wires (for example, combining the wires, but not limited thereto). Specifically, the redistribution structure RDS may adjust the position of the signal output terminal, such that the signal output terminal may not correspond to the signal input terminal. For example, in the integrated circuit unit IU3, the positions of the signal input terminal and the signal output terminal respectively located at two sides of the redistribution structure RDS may respectively correspond to the position of the via V10 (corresponding to the conductive layer CL, for example, corresponding to the drain electrode DE) and the position of the via V11 (corresponding to the conductive pad CP10), and in the top view direction (for example, parallel to the direction Z) of the display device 200, the via V10 may not correspond to the via V11. By making the integrated circuit unit IU3 including the redistribution structure RDS, the difficulty of the binding process of the integrated circuit unit IU3 and the substrate SB1 may be reduced, or the flexibility of the binding process may be improved.

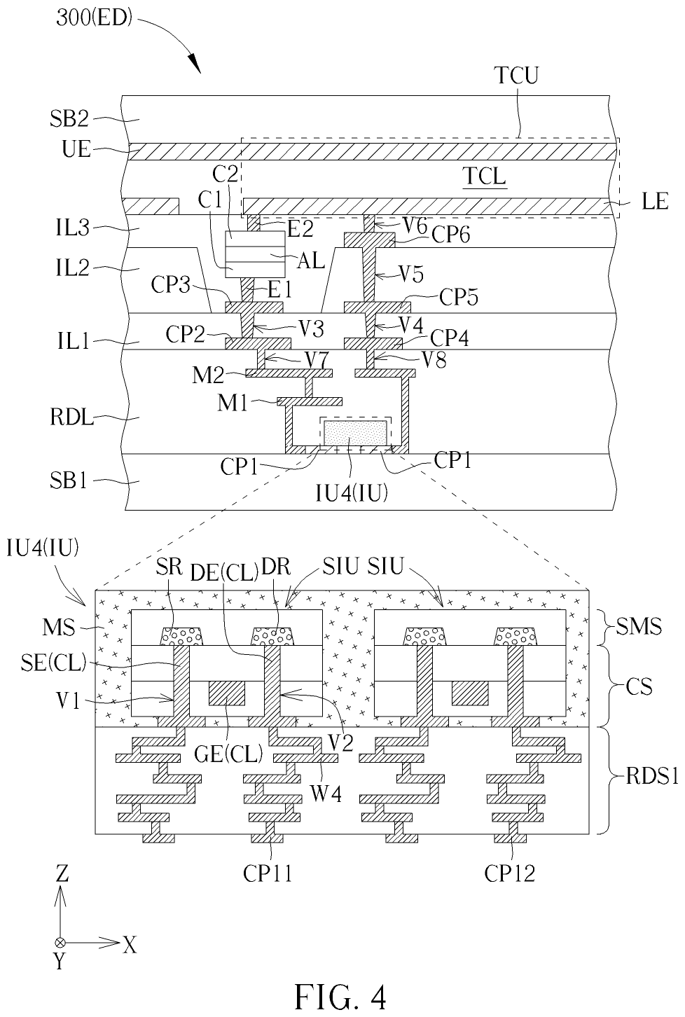

Referring to FIG. 4, FIG. 4 schematically illustrates a cross-sectional view of an electronic device according to a third embodiment of the present disclosure. In the present embodiment, the light emitting unit LU of the display device 300 may for example include a vertical type light emitting diode. That is, the electrode E1 and the electrode E2 of the light emitting unit LU may respectively be located at two sides of the light emitting unit LU, but not limited thereto. In such condition, one of the electrodes of the light emitting unit LU (such as the electrode E1) may be electrically connected to the conductive pad CP3 disposed on the insulating layer IL1, and another one of the electrodes (such as the electrode E2) may be electrically connected to bottom electrode LE of the transparency controllable unit TCU disposed on the insulating layer IL3. In other words, the light emitting unit LU and the transparency controllable unit TCU controlled by the same integrated circuit unit IU may share the bottom electrode LE, but not limited thereto. In addition, in the present embodiment, the bottom electrode LE may be electrically connected to the conductive pad CP6 through the via V6 in the insulating layer IL3, thereby electrically connecting the transparency controllable unit TCU to the integrated circuit unit IU.

The display device 300 of the present embodiment may include the integrated circuit unit IU4 bound on the substrate SB1, wherein the integrated circuit unit IU4 may include two sub integrated circuit units SIU, but not limited thereto. The two sub integrated circuit units SIU may be encapsulated into the integrated circuit unit IU4 through an encapsulation structure MS. In other words, the integrated circuit unit IU4 may include the encapsulation structure MS, wherein the encapsulation structure MS may surround the semiconducting structures SMS and the conductive structures CS of the two sub integrated circuit units SIU. The encapsulation structure MS may include any suitable encapsulation material. The encapsulation material may for example include resin, epoxy resin, other suitable materials or combinations of the above-mentioned materials, but not limited thereto. The structure of the sub integrated circuit unit SIU may refer to the structure of the integrated circuit unit IU shown in FIG. 2, and will not be redundantly described. In other words, the integrated circuit unit IU4 may include the structure formed by encapsulating two integrated circuit units IU. Since the integrated circuit unit IU4 may include two sub integrated circuit units SIU, the light emitting unit LU and the transparency controllable unit TCU may be respectively controlled by the two sub integrated circuit units SIU. For example, the sub integrated circuit unit SIU at the left part of FIG. 4 may be electrically connected to the light emitting unit LU, and the sub integrated circuit unit SIU at the right part of FIG. 4 may be electrically connected to the transparency controllable unit TCU, but not limited thereto. In some embodiments, the integrated circuit unit IU4 may include more sub integrated circuit unit SIU. It should be noted that the integrated circuit unit IU shown in FIG. 2 and the integrated circuit unit IU3 shown in FIG. 3 may be regarded as the embodiment that the integrated circuit unit IU includes a sub integrated circuit unit SIU. In such condition, the light emitting unit LU and the transparency controllable unit TCU may be controlled by the integrated circuit unit IU (or the integrated circuit unit IU3) in a time-sharing way, but not limited thereto.

The integrated circuit unit IU4 may further include a redistribution structure RDS1, wherein the conductive layers CL of the sub integrated circuit unit SIU may be electrically connected to the light emitting unit LU and/or the transparency controllable unit TCU through the redistribution structure RDS1. For example, the conductive layers CL (such as the drain electrode DE) of the sub integrated circuit unit SIU in the left part of the integrated circuit unit IU4 may be introduced to the conductive pad CP11 through the redistribution structure RDS1, wherein the conductive pad CP11 may be electrically connected to the light emitting unit LU; the conductive layers CL (such as the drain electrode DE) of the sub integrated circuit unit SIU in the right part of the integrated circuit unit IU4 may be introduced to the conductive pad CP12 through the redistribution structure RDS1, wherein the conductive pad CP12 may be electrically connected to the transparency controllable unit TCU, but not limited thereto. The redistribution structure RDS1 may for example be formed of a semiconductor material and the wires W4 extending in the semiconductor material, but not limited thereto. In some embodiments, the redistribution structure RDS1 may be replaced with the redistribution structure RDS in the integrated circuit unit IU3. In some embodiments, the integrated circuit unit IU4 may further include the insulating substrate INS, and the encapsulation structure MS may be located between the insulating substrate INS and the redistribution structure RDS1.

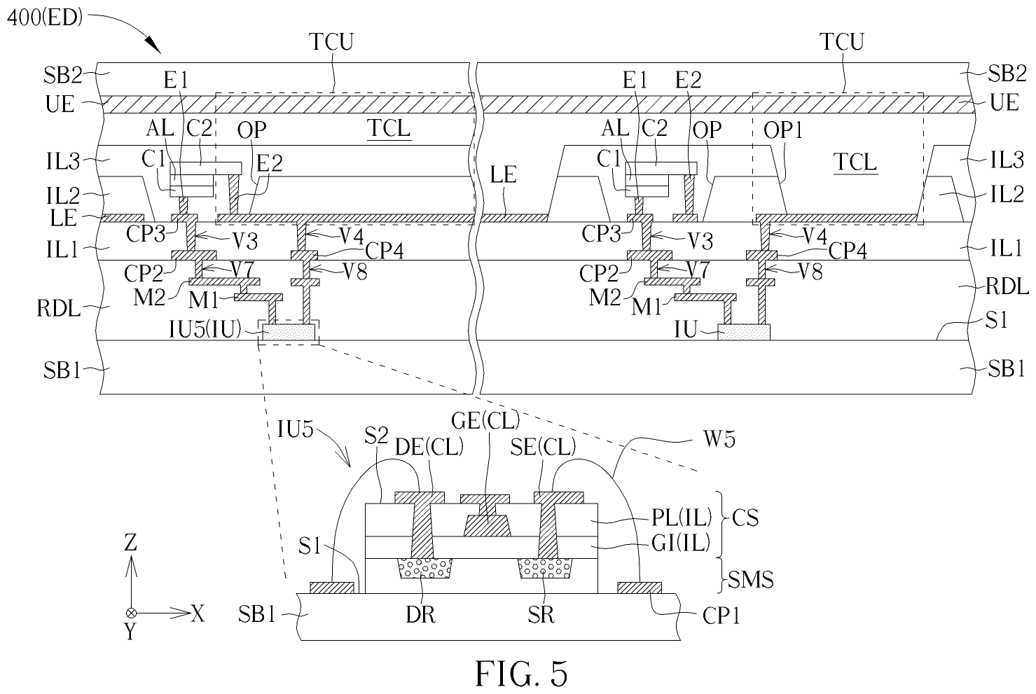

Referring to FIG. 5, FIG. 5 schematically illustrates a cross-sectional view of an electronic device according to a fourth embodiment of the present disclosure. In some embodiments, as shown in FIG. 5 (the left part), the bottom electrode LE of the transparency controllable unit TCU of the display device 400 may be disposed on the insulating layer IL1, and one of the electrodes (for example, the electrode E2) of the light emitting unit LU may be electrically connected to the bottom electrode LE. In other words, the light emitting unit LU and the transparency controllable unit TCU controlled by the same integrated circuit unit IU may share the bottom electrode LE, but not limited thereto. In such condition, the bottom electrode LE of the transparency controllable unit TCU may for example be used as a common electrode, and the top electrode UE of the transparency controllable unit TCU may receive the electrical signals from the integrated circuit unit IU5 (for example, through the wire W2, the conductive material CB, and the like, which are shown in FIG. 2) to adjust the transparency of the transparency controllable unit TCU.

In some embodiments, as shown in FIG. 5 (right part), the bottom electrode LE of the transparency controllable unit TCU of the display device 400 may be disposed on the insulating layer IL1, and at least a portion of the insulating layer IL2 and at least a portion of the insulating layer IL3 corresponding to the bottom electrode LE may be removed to form at least one opening OP1, wherein the opening OP1 may at least partially expose the bottom electrode LE, but not limited thereto. In addition, the transparency controllable layer TCL of the transparency controllable unit TCU may be filled into the opening OP1 and contact the bottom electrode LE. In other words, the transparency controllable layer TCL may for example be disposed between the patterned insulating layers IL2 and/or between the patterned insulating layers IL3. In some embodiments, the opening OP1 may be formed by removing at least a portion of the insulating layer IL3 corresponding to the bottom electrode LE. According to the present embodiment, since a portion of the insulating layer IL2 and/or a portion of the insulating layer IL3 corresponding to the bottom electrode LE may be removed to form the opening OP1, and the transparency controllable layer TCL may be disposed in the opening OP1, the entire thickness of the display device 400 may be reduced, thereby improving the performance of the display device 400.

In some embodiments, the display device 400 may include the integrated circuit unit IU5 bound on the substrate SB1, wherein the integrated circuit unit IU5 may for example be bound on the substrate SB1 through wire bonding. Specifically, as shown in FIG. 5 (the lower part), the integrated circuit unit IU5 may be transferred to the substrate SB1 at first. In such condition, the conductive layers CL (such as the source electrode SE, the drain electrode DE and the gate electrode GE) of the conductive structure CS of the integrated circuit unit IU5 may face upward or may be away from the top surface S1 of the substrate SB1. After that, the drain electrode DE and/or the source electrode SE of the integrated circuit unit IU5 may be electrically connected to the conductive pad CP1 on the top surface S1 of the substrate SB1 through the wires W5, such that the integrated circuit unit IU5 may be bound on the substrate SB1. The integrated circuit unit IU5 may include the semiconducting structure SMS and the conductive structure CS, and the conductive structure CS may include the insulating layers IL and the conductive layers CL, wherein the semiconducting structure SMS may be disposed between the substrate SB1 and the insulating layers IL, and the insulating layers IL may be disposed between the semiconducting structure SMS and the conductive layers CL. In some embodiments, a substrate (not shown) may be included between the semiconducting structure SMS and the substrate SB1, wherein the wires W5 may be bound on the substrate through wire bonding, and then the wires W5 are electrically connected to the substrate SB1 (or the conductive pad CP1 on the substrate SB1) through that substrate.

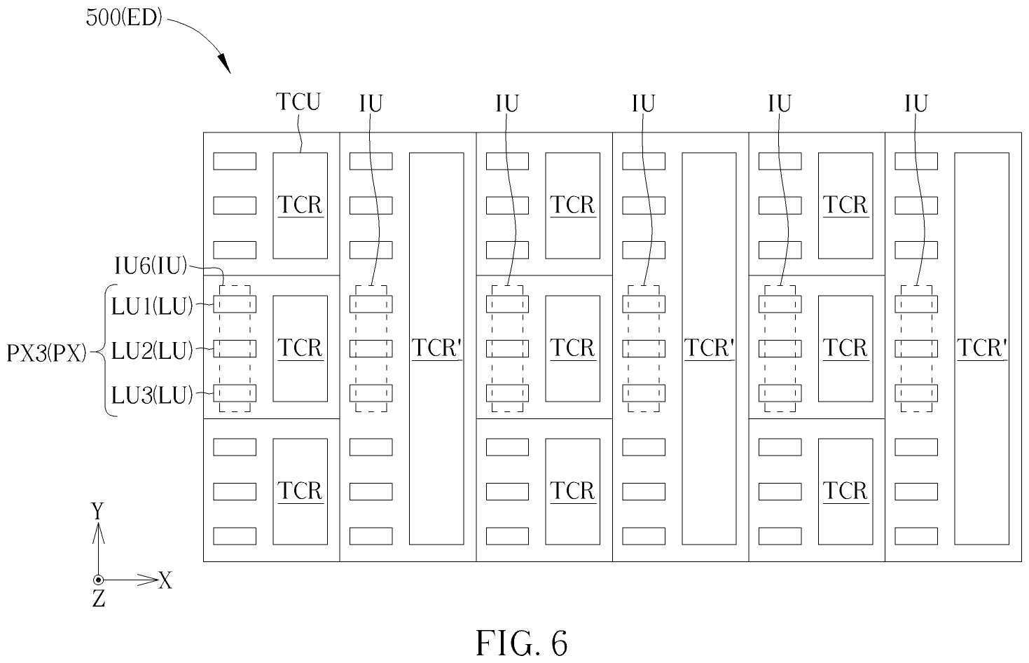

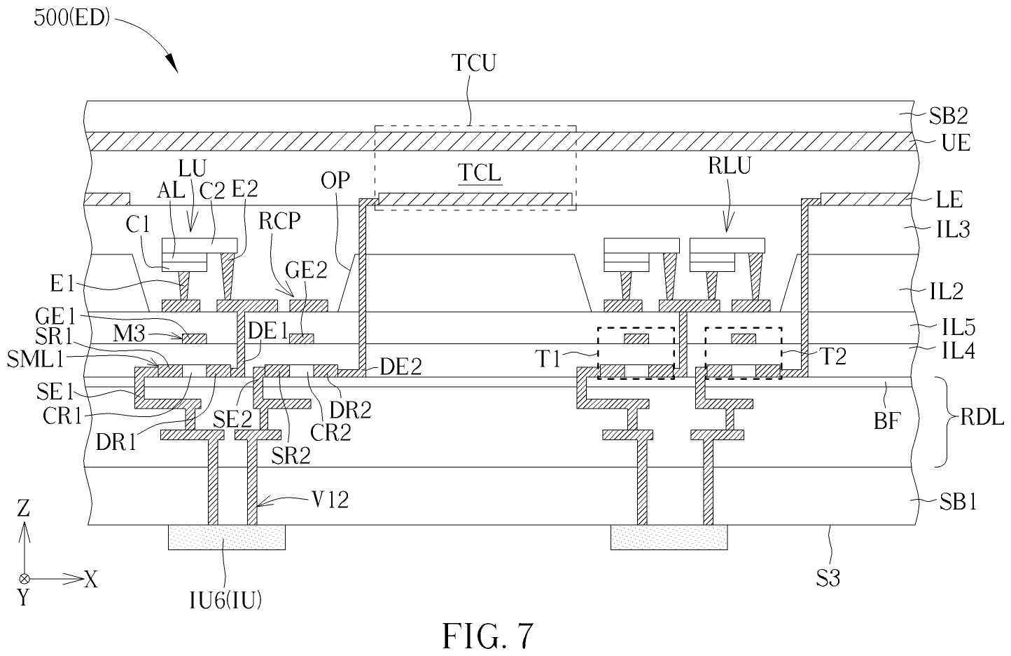

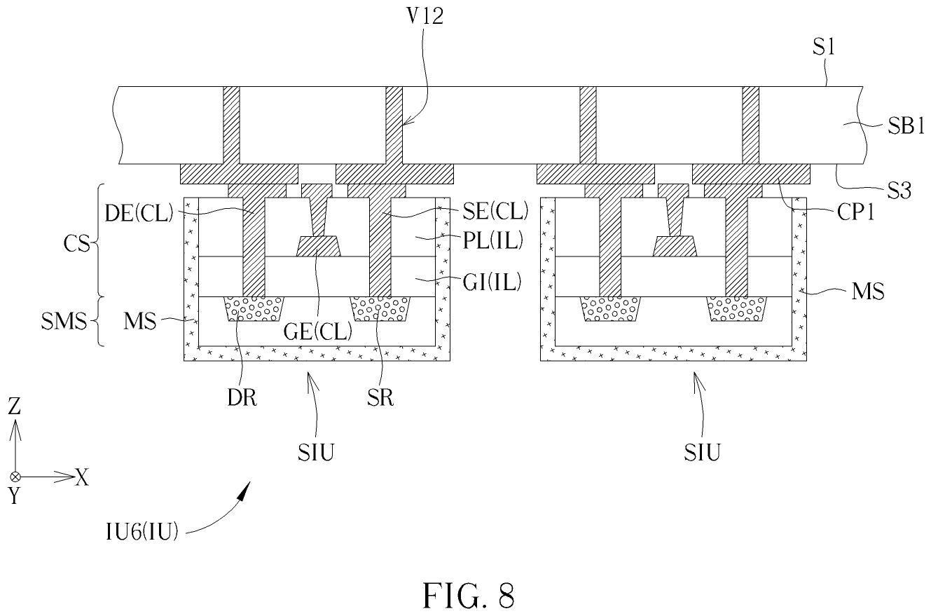

Referring to FIG. 6 to FIG. 8, FIG. 6 schematically illustrates a top view of an electronic device according to a fifth embodiment of the present disclosure, FIG. 7 schematically illustrates a cross-sectional view of the electronic device according to the fifth embodiment of the present disclosure, and FIG. 8 schematically illustrates a cross-sectional view of an integrated circuit unit according to the fifth embodiment of the present disclosure. According to the present embodiment, the display device 500 may include the integrated circuit unit IU6 electrically connected to the light emitting unit LU and the transparency controllable unit TCU, wherein the integrated circuit unit IU6 at least partially overlaps the light emitting unit LU in the top view direction (for example, parallel to the direction Z) of the display device 500. In other words, the integrated circuit unit IU6 may correspond to the light emitting unit LU to which it is electrically connected. For example, as shown in FIG. 6, the display device 500 may include a pixel PX3 composed of a light emitting unit LU1, a light emitting unit LU2 and a light emitting unit LU3, and in the top view direction of the display device 500, the integrated circuit unit IU6 may overlap and be electrically connected to the light emitting unit LU1, the light emitting unit LU2 and the light emitting unit LU3, but not limited thereto. In some embodiments, the integrated circuit unit IU6 may overlap one or two of the light emitting unit LU1, the light emitting unit LU2 and the light emitting unit LU3 in the top view direction of the display device 500. In addition, the integrated circuit unit IU6 may further be electrically connected to the transparency controllable unit TCU adjacent to the pixel PX3, but not limited thereto. By making the integrated circuit unit IU6 corresponding to the light emitting unit LU, the transparency of the display device 500 may be increased, or the influence of the integrated circuit unit IU6 on the display effect of the display device 500 may be reduced.

In some embodiments, the sizes of the transparency controllable units TCU in the display device 500 may be different. In other words, the display device 500 may include a plurality of transparency controllable regions TCR having different sizes. The size of the transparency controllable region TCR may for example indicate the width, the length or the area of the transparency controllable region TCR, but not limited thereto. For example, as shown in FIG. 6, the display device 500 may include a transparency controllable region TCR and a transparency controllable region TCR′ of different sizes, wherein the transparency controllable region TCR may be adjacent to a pixel PX, and the transparency controllable region TCR′ may be adjacent to multiple pixels PX (such as three pixels PX, but not limited thereto). In such condition, an integrated circuit unit IU for controlling the transparency of a transparency controllable region TCR′ may also control the multiple pixels PX adjacent to the transparency controllable region TCR′, but not limited thereto. It should be noted that FIG. 6 just exemplarily shown the structure in which the transparency controllable regions TCR have different sizes, and the present disclosure is not limited thereto.

The display device 500 of the present embodiment may further include a first transistor T1 and a second transistor T2 disposed on the substrate SB1, but not limited thereto. In detail, the redistribution layer RDL of the display device 500 may further include a buffer layer BF, and the display device 500 may include a semiconductor layer SML1 disposed on the buffer layer BF, an insulating layer IL4 disposed on the buffer layer BF and covering the semiconductor layer SML1, a conductive layer M3 disposed on the insulating layer IL4 and an insulating layer IL5 disposed on the insulating layer IL4 and covering the conductive layer M3. The semiconductor layer SML1 may form the source region SR1, the drain region DR1 and the channel region CR1 of the first transistor T1 and the source region SR2, the drain region DR2 and the channel region CR2 of the second transistor T2. The insulating layer IL4 may be the gate insulating layers of the first transistor T1 and the second transistor T2. The conductive layer M3 may form the gate electrode GE1 of the first transistor T1 and the gate electrode GE2 of the second transistor T2. The insulating layer IL4 and the insulating layer IL5 may include any suitable insulating material. The material of the conductive layer M3 may refer to the material of the conductive layer M1 mentioned above.

According to the present embodiment, the first transistor T1 may be electrically connected between the light emitting unit LU and the integrated circuit unit IU (such as the integrated circuit unit IU6), and the second transistor T2 may be electrically connected between the transparency controllable unit TCU and the integrated circuit unit IU (such as the integrated circuit unit IU6), but not limited thereto. In detail, the first transistor T1 may further include the source electrode SE1 electrically connected to the source region SR1 and the drain electrode DE1 electrically connected to the drain region DR1, wherein the source electrode SE1 may be electrically connected to the integrated circuit unit IU6, and the drain electrode DE1 may be electrically connected to the light emitting unit LU. The source electrode SE1 may for example be electrically connected to the redistribution layer RDL through the via (not labeled) penetrating the buffer layer BF, and the drain electrode DE1 may for example be electrically connected to the light emitting unit LU through the via (not labeled) penetrating the insulating layer IL4 and the insulating layer IL5, but not limited thereto. The second transistor T2 may further include the source electrode SE2 electrically connected to the source region SR2 and the drain electrode DE2 electrically connected to the drain region DR2, wherein the source electrode SE2 may be electrically connected to the integrated circuit unit IU6, and the drain electrode DE2 may be electrically connected to the transparency controllable unit TCU. The source electrode SE2 may for example be electrically connected to the redistribution layer RDL through the via (not labeled) penetrating through the buffer layer BF, and the drain electrode DE2 may for example be electrically connected to the transparency controllable unit TCU through the via (not labeled) penetrating through the insulating layer IL4, the insulating layer IL5, the insulating layer IL2 and the insulating layer IL3, but not limited thereto. The electrical connecting ways of the first transistor T1 and the second transistor T2 mentioned above are exemplary, and the present disclosure is not limited thereto. In some embodiments, the integrated circuit unit IU6 may be electrically connected to the gate electrode GE1 of the first transistor T1 and the gate electrode GE2 of the second transistor T2.

In the present embodiment, the integrated circuit unit IU6 may control the light emission of the light emitting unit LU (or the transparency of the transparency controllable unit TCU) through the first transistor T1 (or the second transistor T2). In other words, the integrated circuit unit IU6 and the first transistor T1 may be used as the driving unit of the light emitting unit LU, and the integrated circuit unit IU6 and the second transistor T2 may be used as the driving unit of the transparency controllable unit TCU. Specifically, the integrated circuit unit IU6 may control on/off of the first transistor T1 and the second transistor T2, and the first transistor T1 and the second transistor T2 may respectively control the light emission of the light emitting unit LU and the transparency of the transparency controllable unit TCU. In addition, in the present embodiment, the integrated circuit unit IU6 may be electrically connected to a plurality of first transistors T1 and a plurality of second transistors T2 at the same time to control a plurality of light emitting units LU and a plurality of transparency controllable units TCU, but not limited thereto. Specifically, a plurality of light emitting units LU and a plurality of transparency controllable units TCU may be respectively controlled by a plurality of first transistors T1 and a plurality of second transistors T2, wherein the plurality of first transistors T1 and the plurality of second transistors T2 may be electrically connected to the same integrated circuit unit IU6, such that the integrated circuit unit IU6 may control on/off of the plurality of first transistors T1 and the plurality of second transistors T2. For example, the integrated circuit unit IU6 shown in FIG. 6 may further be electrically connected to the light emitting units LU in other pixels (for example, the pixels above and/or below the pixel PX3) in addition to the pixel PX3 to control those light emitting units LU, but not limited thereto. Through the above-mentioned design, a plurality of light emitting units LU (or pixels PX) and a plurality of transparency controllable units TCU may be controlled by an integrated circuit unit IU6. Therefore, the numbers of the integrated circuit unit IU6 and/or the wires may be reduced to simplify the layout of the wires, or the production cost may be reduced.

According to the present embodiment, the first transistor T1 and the second transistor T2 may be disposed corresponding to the disposition position of the light emitting unit LU, but not limited thereto. For example, the first transistor T1 and the second transistor T2 may be disposed corresponding to the opening OP in the insulating layer IL2. Therefore, the influence of the first transistor T1 and the second transistor T2 on the transparency of the display device 500 may be reduced, thereby improving the display effect of the display device 500.

In some embodiments, as shown in FIG. 7 (the right part), the display device 500 may further include a dummy light emitting unit RLU, wherein the dummy light emitting unit RLU and the light emitting unit LU may be disposed in the same opening OP, but not limited thereto. The dummy light emitting unit RLU may for example be used as a spare light emitting unit of the light emitting unit LU, but not limited thereto. The light emitting unit LU and the dummy light emitting unit RLU located in the same opening OP may be electrically connected to the same first transistor T1 to simplify the layout design, but not limited thereto. In some embodiments, as shown in FIG. 7 (the left part), the display device 500 may include a dummy conductive pad RCP instead of the dummy light emitting unit RLU, and a dummy conductive pad RCP and the light emitting unit LU located in the same opening OP as the dummy conductive pad RCP may be electrically connected to the same first transistor T1.

As shown in FIG. 8, the integrated circuit unit IU6 of the present embodiment may include two sub integrated circuit units SIU, wherein the two sub integrated circuit units SIU may respectively be encapsulated through the encapsulation structure MS. In other words, the semiconducting structures SMS and the conductive structures CS of the two sub integrated circuit units SIU may respectively be surrounded by the encapsulation structure MS, and the two sub integrated circuit units SIU are not connected to each other through the encapsulation structure MS. The structural features of the sub integrated circuit unit SIU may refer to the above-mentioned contents, and will not be redundantly described.

According to the present embodiment, the integrated circuit unit IU6 may be bound under the substrate SB1 and be electrically connected to the redistribution layer RDL through a via V12 penetrating through the substrate SB1, but not limited thereto. Specifically, the substrate SB1 may include a bottom surface S3 opposite to the top surface S1, the conductive pad CP1 may be disposed on the bottom surface S3, and the sub integrated circuit units SIU of the integrated circuit unit IU6 may be bound to the conductive pad CP1 in a way that the conductive structure CS faces the bottom surface S3, such that the integrated circuit unit IU6 may be bound under the substrate SB1. In addition, the conductive pad CP1 may be electrically connected to the redistribution layer RDL on the substrate SB1 through the via V12 in the substrate SB1, such that the integrated circuit unit IU6 may be electrically connected to the light emitting unit LU and/or the transparency controllable unit TCU. The integrated circuit unit IU6 may include the semiconducting structure SMS and the conductive structure CS, and the conductive structure CS may include the conductive layers CL and the insulating layers IL, wherein the conductive layers CL may be disposed between the substrate SB1 and the insulating layers IL, and the insulating layers IL may be disposed between the conductive layers CL and the semiconducting structure SMS.

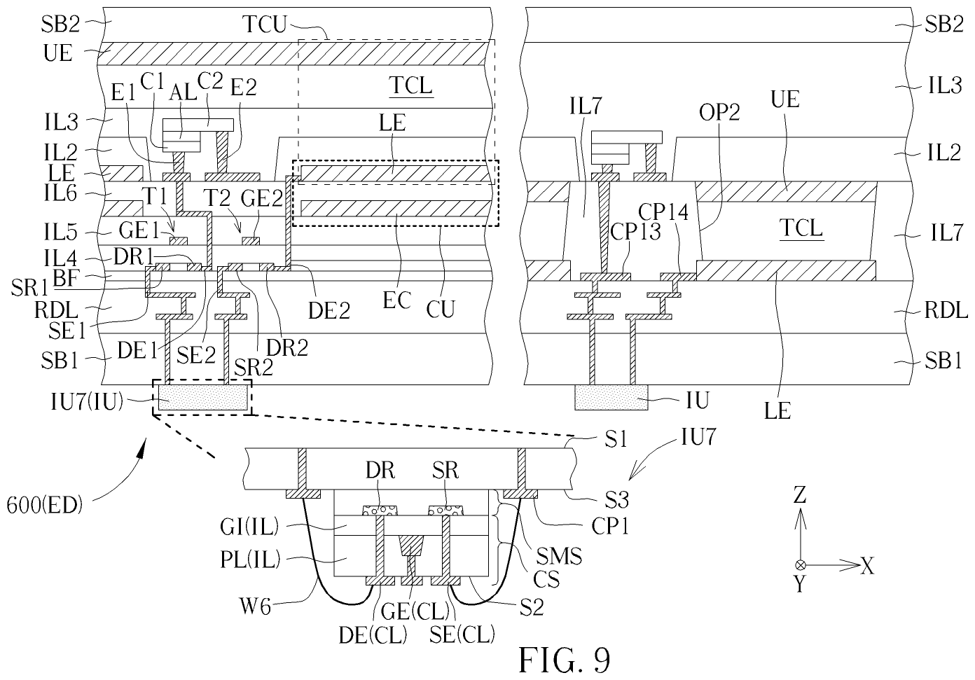

Referring to FIG. 9, FIG. 9 schematically illustrates a cross-sectional view of an electronic device according to a sixth embodiment of the present disclosure. In some embodiments, as shown in FIG. 9 (the left part), the display device 600 may further include an insulating layer IL6 and an electrode EC disposed on the substrate SB1, wherein the electrode EC may be disposed on the insulating layer IL5, and the insulating layer IL6 may be disposed on the insulating layer IL5 and cover the electrode EC. The bottom electrode LE of the transparency controllable unit TCU may be disposed on the insulating layer IL6, but not limited thereto. According to the present embodiment, in the top view direction (for example, parallel to the direction Z) of the display device 600, the electrode EC may at least partially overlap the transparency controllable unit TCU or at least partially overlap the bottom electrode LE and/or the top electrode UE. The electrode EC and one of the bottom electrode LE and the top electrode UE may form a capacitor CU, and in the top view direction of the display device 600, the capacitor CU may at least partially overlap the transparency controllable unit TCU. For example, the capacitor CU of the present embodiment may be formed of the electrode EC and the bottom electrode LE, but not limited thereto. Since the display device 600 may further include the capacitor CU corresponding to the transparency controllable unit TCU, the capacitor CU may be used as the storage capacitor of the transparency controllable unit TCU to improve the stability of the transparency controllable unit TCU, thereby improving the display effect of the display device 600. It should be noted that the electrode EC may be disposed at any suitable position in the display device 600, which is not limited to the structure shown in FIG. 9. In addition, in the present embodiment, the light emitting unit LU and the transparency controllable unit TCU may respectively be electrically connected to the first transistor T1 and the second transistor T2 through the vias (not labeled) penetrating through the insulating layer IL6, the insulating layer IL5 and the insulating layer IL4, but not limited thereto.

In some embodiments, as shown in FIG. 9 (the right part), the display device 600 may further include an insulating layer IL7 disposed on the redistribution layer RDL, wherein a portion of the insulating layer IL7 corresponding to the insulating layer IL2 may be removed to form an opening OP2, but not limited thereto. In other words, the opening OP2 may not correspond to the light emitting unit LU. According to the present embodiment, the transparency controllable unit TCU may be disposed in the opening OP2 formed by removing a portion of the insulating layer IL7. For example, the bottom electrode LE and the insulating layer IL7 covering the bottom electrode LE may be disposed on the redistribution layer RDL at first, and then a portion of the insulating layer IL7 corresponding to the insulating layer IL2 may be removed to form the opening OP2, and the transparency controllable layer TCL and the top electrode UE may be disposed in the opening OP2 in sequence, thereby forming the transparency controllable unit TCU. Since the opening OP2 may not correspond to the light emitting unit LU, the transparency controllable unit TCU in the opening OP2 may not be disposed corresponding to the light emitting unit LU. In addition, the display device 600 may further include a conductive pad CP13 and a conductive pad CP14 disposed on the redistribution layer RDL, wherein the insulating layer IL7 may cover the conductive pad CP13 and the conductive pad CP14. The light emitting unit LU may be electrically connected to the conductive pad CP13 through the via (not labeled) penetrating through the insulating layer IL7, the bottom electrode LE of the transparency controllable unit TCU may be electrically connected to the conductive pad CP14, and the conductive pad CP13 and the conductive pad CP14 may be electrically connected to the integrated circuit unit IU through the redistribution layer RDL and the vias (not labeled) penetrating through the substrate SB1, but not limited thereto. The electrical connecting ways between the integrated circuit unit IU and the light emitting unit LU (or the transparency controllable unit TCU) mentioned above are exemplary, and the present disclosure is not limited thereto. By making the transparency controllable unit TCU disposed in the opening OP2 formed by removing a portion of the insulating layer IL7, the entire thickness of the display device 600 may be reduced, thereby improving the performance of the display device 600.

The display device 600 of the present embodiment may include an integrated circuit unit IU7, wherein the integrated circuit unit IU7 may be disposed under the substrate SB1 through wire bonding. The structural features of the integrated circuit unit IU7 may refer to the contents in the above-mentioned embodiments, and will not be redundantly described. Specifically, as shown in FIG. 9 (the lower part), the integrated circuit unit IU7 may be transferred under the substrate SB1 in the way that the surface S2 of the integrated circuit unit IU7 is away from the bottom surface S3 of the substrate SB1. After that, the drain electrode DE and/or the source electrode SE of the integrated circuit unit IU7 may be electrically connected to the conductive pad CP1 on the bottom surface S3 of the substrate SB1 through the wire W6, thereby binding the integrated circuit unit IU7 to the substrate SB1. The integrated circuit unit IU7 may include the semiconducting structure SMS and the conductive structure CS, the conductive structure CS may include the conductive layers CL and the insulating layers IL, wherein the semiconducting structure SMS may be disposed between the substrate SB1 and the insulating layers IL, and the insulating layers IL may be disposed between the semiconducting structure SMS and the conductive layers CL.

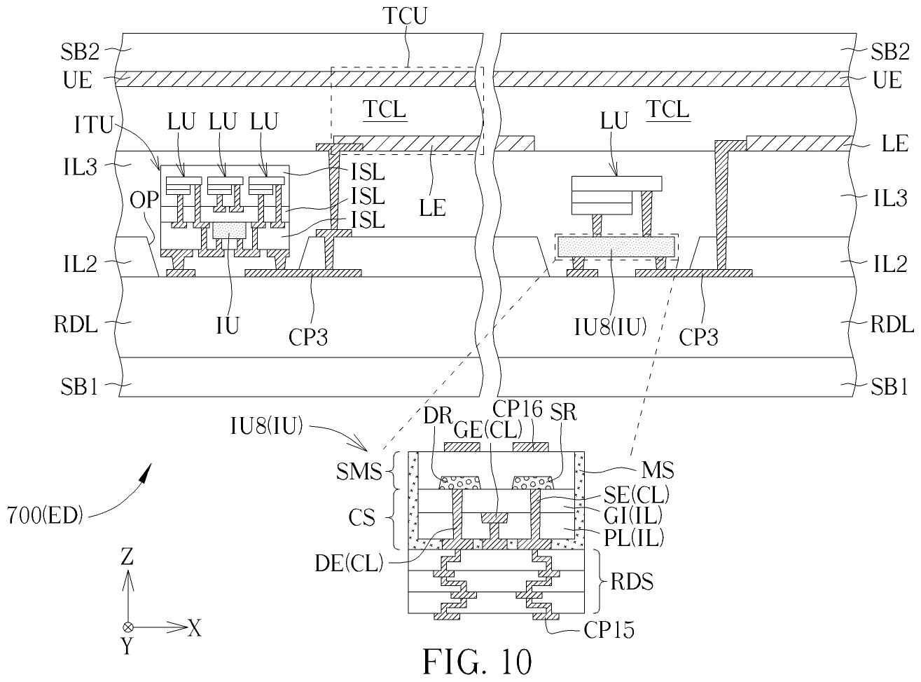

Referring to FIG. 10, FIG. 10 schematically illustrates a cross-sectional view of an electronic device according to a seventh embodiment of the present disclosure. According to the present embodiment, the display device 700 may include an integrated unit ITU, wherein the integrated unit ITU may be disposed on the substrate SB1. Specifically, the integrated unit ITU may be disposed in the opening OP in the insulating layer IL2 and electrically connected to the conductive pad CP3, but not limited thereto. The integrated unit ITU may include the light emitting units LU, the integrated circuit unit IU, a plurality of insulating layers ISL and a plurality of wires and/or conductive pads (not labeled), wherein the wires may penetrate through the insulating layers ISL, such that the integrated circuit unit IU may be electrically connected to the light emitting units LU through the wires and/or the conductive pads, but not limited thereto. In other words, in the present embodiment, an integrated circuit unit IU and the light emitting units LU electrically connected to the integrated circuit unit IU may be integrated to be the integrated unit ITU at first, and then the integrated unit ITU may be disposed in the opening OP. It should be noted that the structure of the integrated unit ITU of the present embodiment is not limited to what is shown in FIG. 10, and the integrated unit ITU may include any suitable structure according to the demands of the design of the product. In addition, in the present embodiment, the integrated circuit unit IU in the integrated unit ITU may be electrically connected to the conductive pad CP3 by electrically connecting the integrated unit ITU to the conductive pad CP3, and the conductive pad CP3 may be electrically connected to the bottom electrode LE of the transparency controllable unit TCU through the wires and/or the conductive pads (not labeled) penetrating through the insulating layer IL2 and the insulating layer IL3, but not limited thereto. Therefore, the integrated circuit unit IU of the integrated unit ITU may be electrically connected to the transparency controllable unit TCU.

As shown in FIG. 10 (the right part), the display device 700 of the present embodiment may include an integrated circuit unit IU8, wherein the integrated circuit unit IU8 may be located in the opening OP in the insulating layer IL2, and the light emitting unit LU may be disposed on the integrated circuit unit IU8. Specifically, the integrated circuit unit IU8 may be bound on the conductive pad CP3, and the light emitting unit LU may be bound on the integrated circuit unit IU8, but not limited thereto. In some embodiments, the integrated circuit unit IU8 may be bound on the conductive pad CP3 at first, and then the light emitting unit may be bound on the integrated circuit unit IU8. In some embodiments, the light emitting unit LU may be bound on the integrated circuit unit IU8 at first (that is, the light emitting unit LU and the integrated circuit unit IU8 are integrated), and then the integrated circuit unit IU8 may be bound to the conductive pad CP3. The integrated circuit unit IU8 may include the semiconducting structure SMS, the conductive structure CS, the encapsulation structure MS surrounding the semiconducting structure SMS and the conductive structure CS, and the redistribution structure RDS electrically connected to the conductive structure CS, but not limited thereto. The features of the elements in the integrated circuit unit IU8 may refer to the contents mentioned above, and will not be redundantly described. The redistribution structure RDS may be used to introduce the source electrode SE and/or the drain electrode DE of the conductive structure CS to a conductive pad CP15 at a side of the redistribution structure RDS opposite to the conductive structure CS. In addition, the integrated circuit unit IU8 may further include a conductive element at a side of the semiconducting structure SMS, such as the conductive pad CP16, but not limited thereto. In the present embodiment, one of the conductive pad CP15 and the conductive pad CP16 which are respectively located at two sides of the integrated circuit unit IU8 may be electrically connected to the conductive pad CP3, thereby being electrically connected to the bottom electrode LE of the transparency controllable unit TCU, and another one of the conductive pad CP15 and the conductive pad CP16 may be electrically connected to the electrode E1 and/or the electrode E2 of the light emitting unit LU, thereby being electrically connected to the light emitting unit LU. It should be noted that the structure of the integrated circuit unit IU8 is not limited to what is shown in FIG. 10, and the integrated circuit unit IU8 may include any suitable structure.

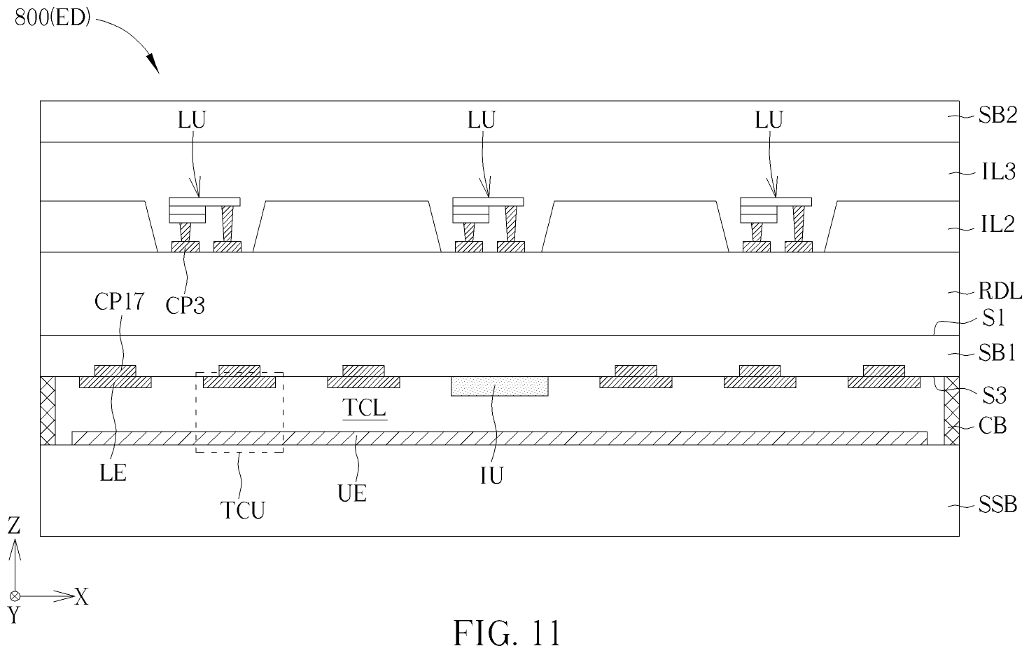

Referring to FIG. 11, FIG. 11 schematically illustrates a cross-sectional view of an electronic device according to an eighth embodiment of the present disclosure. According to the present embodiment, the transparency controllable unit TCU of the display device 800 may be disposed under the substrate SB1 or disposed on the bottom surface S3 of the substrate SB1. For example, the transparency controllable unit TCU including the bottom electrode LE, the transparency controllable layer TCL and the top electrode UE may be formed at first, and then the transparency controllable unit TCU may be disposed on the bottom surface S3 of the substrate SB1, but not limited thereto. The bottom electrode LE, the transparency controllable layer TCL and the top electrode UE may for example be disposed on a substrate SSB, but not limited thereto. “The bottom electrode LE and the top electrode UE” mentioned above are named by considering the order in the process, which does not represent the relative positions of the bottom electrode LE and the top electrode UE in the display device 800. In other words, the transparency controllable unit TCU of the present embodiment may be an out-cell unit, but not limited thereto. In some embodiments, the transparency controllable unit TCU may be disposed on the bottom surface S3 in the way that the bottom electrode LE faces the bottom surface S3. In some embodiments, the transparency controllable unit TCU may be disposed on the bottom surface S3 in the way that the top electrode UE faces the bottom surface S3.

In addition, the top electrode and/or the bottom electrode LE of the transparency controllable unit TCU may be patterned, but not limited thereto. For example, as shown in FIG. 11, the bottom electrode LE of the transparency controllable unit TCU may be patterned, but not limited thereto. Therefore, a plurality of transparency controllable unit TCU may be formed. In some embodiments, the bottom electrode LE may be an entire layer, and the top electrode UE may be patterned. In some embodiments, the bottom electrode LE and the top electrode UE may be patterned. In some embodiments, the bottom electrode LE and the top electrode UE may respectively be an entire layer. By making at least one of the top electrode UE and the bottom electrode LE being patterned, the effect of locally controlling the transparency in the display device 800 may be achieved, thereby improving the performance of the display device 800. Specifically, the size or position of the transparency controllable unit TCU may be adjusted by patterning the top electrode UE and/or the bottom electrode LE, thereby achieving the effect of controlling the transparency of any region of the display device 800.

In order to simplify the figure, the layout of the wires is not shown in FIG. 11, but the present embodiment is not limited thereto. In some embodiments, the light emitting unit LU may be electrically connected to the conductive pad CP3, thereby being electrically connected to the integrated circuit unit IU bound under the substrate SB1 through the conductive pad CP3 and the redistribution layer RDL. In some embodiments, the bottom electrode LE may be electrically connected to the conductive pad CP17, thereby being electrically connected to the integrated circuit unit IU through the conductive pad CP17. In some embodiments, the top electrode UE may be electrically connected to the conductive material CB, thereby being electrically connected to the integrated circuit unit IU through the conductive material CB. In some embodiments, the integrated circuit unit IU may be bound on the substrate SB1.

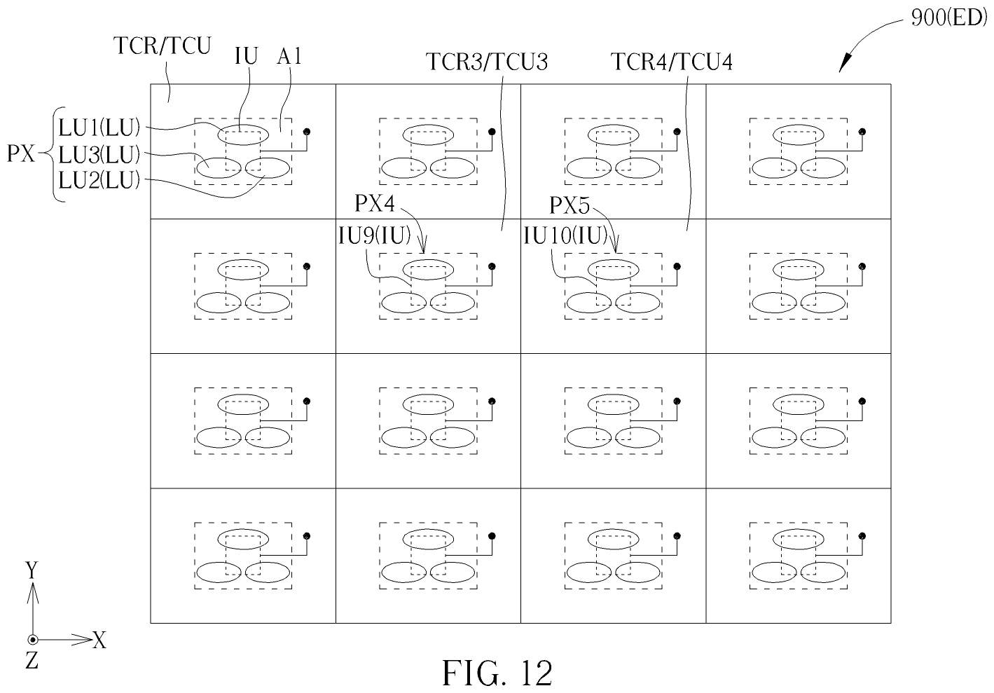

Referring to FIG. 12, FIG. 12 schematically illustrates a top view of an electronic device according to a ninth embodiment of the present disclosure. In order to simplify the figure, FIG. 12 just exemplarily shows the disposition positions of the light emitting units LU, the transparency controllable units TCU and the integrated circuit units IU, and the detailed structures thereof are not limited to what is shown in FIG. 12. According to the present embodiment, in the top view direction (for example, parallel to the direction Z) of the display device 900, the transparency controllable unit TCU may surround the integrated circuit unit IU and/or the light emitting unit LU, but not limited thereto. Specifically, the transparency controllable unit TCU may be ring-shaped and surround an area A1 in the top view direction (for example, parallel to the direction Z) of the display device 900, and the binding positions of the integrated circuit unit IU and the light emitting unit LU may correspond to the area A1. The transparency controllable unit TCU may not be disposed corresponding to the area A1. In other words, at least one of the top electrode UE, the bottom electrode LE and the transparency controllable layer TCL may not be included in the area A1. In addition, the integrated circuit unit IU may overlap at least one of the light emitting units LU in the top view direction of the display device 900, or the integrated circuit unit IU may partially overlap one or more light emitting units LU in the top view direction of the display device 900, but not limited thereto. Since the range of the transparency controllable region TCR may be defined by the transparency controllable unit TCU, the transparency controllable region TCR may surround the integrated circuit unit IU and the light emitting unit LU. It should be noted that the shape of the transparency controllable unit TCU (or the transparency controllable region TCR) shown in FIG. 12 is exemplary, and the present embodiment is not limited thereto.

As shown in FIG. 12, in the present embodiment, a transparency controllable unit TCU may surround an integrated circuit unit IU and light emitting units in a pixel PX (such as the light emitting unit LU1, the light emitting unit LU2 and the light emitting unit LU3), and the integrated circuit unit IU may be electrically connected to the transparency controllable unit TCU and the light emitting units LU in the pixel PX, but not limited thereto. In some other embodiments, a transparency controllable unit TCU may surround a plurality of pixels PX disposed in a plurality of areas A1 and an integrated circuit unit IU, wherein the integrated circuit unit IU may correspond to one of the plurality of areas A1, and the integrated circuit unit IU may be electrically connected to the transparency controllable unit TCU and the light emitting units LU in the plurality of pixels PX. In other words, an integrated circuit unit IU may be used to control a transparency controllable unit TCU and the light emitting units LU in the plurality of pixels PX surrounded by the transparency controllable unit TCU.

In the present embodiment, as shown in FIG. 12, the transparency controllable units TCU (or transparency controllable regions TCR) controlled by different integrated circuit units IU may not overlap each other in the top view direction of the display device 900. For example, the integrated circuit unit IU9 may control the transparency controllable unit TCU3 and the pixel PX4, and the integrated circuit unit IU10 may control the transparency controllable unit TCU4 and the pixel PX5, wherein the transparency controllable unit TCU3 and the transparency controllable unit TCU4 may not overlap each other in the top view direction of the display device 900. In such condition, when the integrated circuit unit IU9 and the integrated circuit unit IU10 respectively control the light emitting units LU in the pixel PX4 and the light emitting units LU in the pixel PX5 to emit light, the integrated circuit unit IU9 and the integrated circuit unit IU10 may respectively control the transparency controllable unit TCU3 and the transparency controllable unit TCU4 to reduce the transparency of the transparency controllable unit TCU3 and the transparency of the transparency controllable unit TCU4, thereby increasing the contrast of the images displayed by the light emitting units LU in the pixel PX4 and the light emitting units LU in the pixel PX5. The configurations of the integrated circuit unit IU and the transparency controllable unit TCU of the present disclosure are not limited to the above-mentioned contents. In some other embodiments, the transparency controllable units TCU (or transparency controllable regions TCR) controlled by different integrated circuit units IU may partially overlap each other in the top view direction of the display device 900. In other words, a portion of the transparency controllable unit TCU may be controlled by two or more integrated circuit units IU.

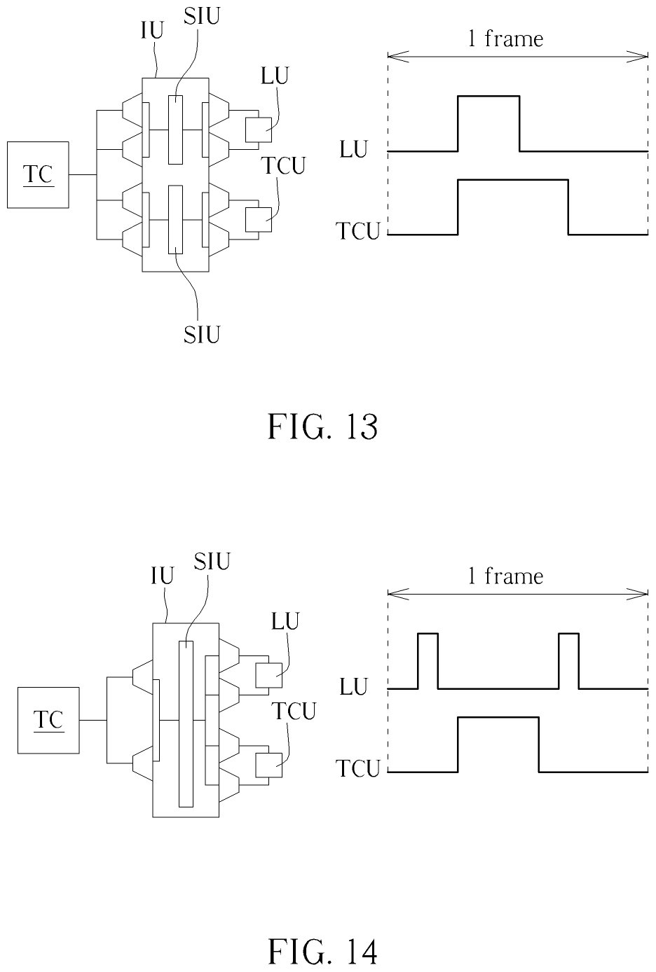

Referring to FIG. 13 and FIG. 14, FIG. 13 schematically illustrates a controlling way of an integrated circuit unit according to an embodiment of the present disclosure, and FIG. 14 schematically illustrates a controlling way of an integrated circuit unit according to another embodiment of the present disclosure. Specifically, FIG. 13 shows the controlling way of the integrated circuit unit IU including two sub integrated circuit units SIU, and FIG. 14 shows the controlling way of the integrated circuit unit IU including one sub integrated circuit unit SIU. The integrated circuit unit IU shown in FIG. 13 may for example include the integrated circuit unit IU4 shown in FIG. 4 or the integrated circuit unit IU6 shown in FIG. 7, but not limited thereto. The integrated circuit unit IU shown in FIG. 14 may for example include the integrated circuit unit IU shown in FIG. 2, the integrated circuit unit IU3 shown in FIG. 3, the integrated circuit unit IU5 shown in FIG. 5, the integrated circuit unit IU7 shown in FIG. 9 or the integrated circuit unit IU8 shown in FIG. 10, but not limited thereto.

As shown in FIG. 13, when the integrated circuit unit IU includes two sub integrated circuit units SIU, one of the two sub integrated circuit units SIU may be electrically connected to the light emitting unit LU, and another one of the two sub integrated circuit units SIU may be electrically connected to the transparency controllable unit TCU. In addition, the two sub integrated circuit units SIU may further be electrically connected to a time controller TC, but not limited thereto. The right half of FIG. 13 shows the voltage changes of the light emitting unit LU and the transparency controllable unit TCU in one frame. In the present embodiment, since the light emitting unit LU and the transparency controllable unit TCU may be controlled by different sub integrated circuit units SIU, the light emitting unit LU and the transparency controllable unit TCU may be driven simultaneously, but not limited thereto. In addition, according to the characteristics or response times of the light emitting unit LU and the transparency controllable unit TCU, the driving time of the light emitting unit LU and the driving time of the transparency controllable unit TCU may be different. For example, in a frame, it may start to drive the light emitting unit LU and the transparency controllable unit TCU at the same time, and the driving time of the transparency controllable unit TCU may be longer than the driving time of the light emitting unit LU, such that the end of driving of the light emitting unit LU may be earlier than the end of driving of the transparency controllable unit TCU, but not limited thereto. In some embodiments, in a frame, the transparency controllable unit TCU may be driven earlier than the light emitting unit LU, and the end of driving of the transparency controllable unit TCU and the end of driving of the light emitting unit LU may occur at the same time. Since the response time of the transparency controllable unit TCU may be longer than the response time of the light emitting unit LU, the above-mentioned driving methods may improve the performance of the transparency controllable unit TCU, thereby improving the display effect. In some embodiments, in a frame, the light emitting unit LU may be driven earlier than the transparency controllable unit TCU, and the end of driving of the light emitting unit LU may be earlier than the end of driving of the transparency controllable unit TCU. In some embodiments, in a frame, the light emitting unit LU may for example be driven through pulse width modulation (PWM), that is, the driving time of the light emitting unit LU may be shorter than the driving time of the transparency controllable unit TCU, and the amplitude (shown in FIG. 13) representing the voltage change of the light emitting unit LU may be greater than the amplitude representing the voltage change of the transparency controllable unit TCU. It should be noted that the above-mentioned driving methods are exemplary, and the present embodiment is not limited thereto.

As shown in FIG. 14, when the integrated circuit unit IU includes a sub integrated circuit unit SIU, the sub integrated circuit unit SIU may be electrically connected to the time controller TC, and the light emitting unit LU and the transparency controllable unit TCU may be electrically connected to the sub integrated circuit unit SIU. The right half of FIG. 14 shows the voltage changes of the light emitting unit LU and the transparency controllable unit TCU in one frame. In the present embodiment, since the light emitting unit LU and the transparency controllable unit TCU are controlled by the same sub integrated circuit unit SIU, the time interval of driving the light emitting unit LU may not overlap the time interval of driving the transparency controllable unit TCU. Specifically, time sharing signals may be provided by the time controller TC, such that the light emitting unit LU and the transparency controllable unit TCU may be driven at different times by the sub integrated circuit unit SIU in a time sharing way. For example, as shown in FIG. 14, in a frame, the light emitting unit LU may be driven twice, and the transparency controllable unit TCU may be driven in the time interval between the two driving of the light emitting unit LU, but not limited thereto. In other words, in a frame, the times of driving of the light emitting unit LU may be different from the times of driving of the transparency controllable unit TCU. In some embodiments, in a frame, the light emitting unit LU may for example be driven once through pulse width modulation, and the transparency controllable unit TCU may be driven in a time interval different form the time interval in which the light emitting unit LU is driven, wherein the amplitude (shown in FIG. 14) representing the voltage change of the light emitting unit LU may be greater than the amplitude representing the voltage change of the transparency controllable unit TCU.

In summary, a transparency controllable display device is provided by the present disclosure, which includes the light emitting unit, the transparency controllable unit and the integrated circuit unit electrically connected to the light emitting unit and the transparency controllable unit. Since the integrated circuit unit may include a chip bound to the substrate, the transparency of the display device may be increased, thereby improving the display effect of the display device. In addition, when the integrated circuit unit controls a light emitting unit to emit light and display images, the transparency of the transparency controllable unit adjacent to the light emitting unit may be reduced through the integrated circuit unit, such that the contrast of the image displayed by the light emitting unit may be increased, thereby improving the display effect of the display device. Therefore, the display effect of the display device may be improved under the condition that the transparency of the display device is increased.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A display device comprising:
a substrate;
at least one light emitting unit bound on the substrate;
a transparency controllable unit disposed on the substrate; and
an integrated circuit unit overlapped with the substrate and comprising a semiconducting structure and a conductive structure overlapped with the semiconducting structure,
wherein the integrated circuit unit is electrically connected to the at least one light emitting unit and the transparency controllable unit.

2. The display device of claim 1, wherein the conductive structure comprises a conductive layer and an insulating layer disposed between the semiconducting structure and the conductive layer.

3. The display device of claim 2, wherein a material of the semiconducting structure comprises silicon carbide (SiC), silicon (Si), germanium (Ge), gallium arsenide (GaAs), indium phosphide (InP) or gallium nitride (GaN).

4. The display device of claim 2, wherein the integrated circuit unit is bound on the substrate, the semiconducting structure is disposed between the substrate and the insulating layer, and the insulating layer is disposed between the semiconducting structure and the conductive layer.

5. The display device of claim 2, wherein the integrated circuit unit is bound on the substrate, the conductive layer is disposed between the substrate and the insulating layer, and the insulating layer is disposed between the conductive layer and the semiconducting structure.

6. The display device of claim 2, wherein the integrated circuit unit is bound under the substrate, the semiconducting structure is disposed between the substrate and the insulating layer, and the insulating layer is disposed between the semiconducting structure and the conductive layer.

7. The display device of claim 2, wherein the integrated circuit unit is bound under the substrate, the conductive layer is disposed between the substrate and the insulating layer, and the insulating layer is disposed between the conductive layer and the semiconducting structure.

8. The display device of claim 1, wherein the semiconducting structure comprises an insulating substrate and a semiconducting layer, and the conductive structure comprises a conductive layer and an insulating layer; and
wherein the semiconducting layer is disposed between the insulating substrate and the insulating layer, and the insulating layer is disposed between the semiconducting layer and the conductive layer.

9. The display device of claim 1, wherein the integrated circuit unit comprises a molding structure surrounding the semiconducting structure and the conductive structure.

10. The display device of claim 1, wherein the integrated circuit unit comprises a redistribution structure, wherein the at least one light emitting unit and the transparency controllable unit are electrically connected to the conductive structure through the redistribution structure.

11. The display device of claim 1, wherein the at least one light emitting unit comprises at least three light emitting units, and the integrated circuit unit is electrically connected to the at least three light emitting units and electrically connected to the transparency controllable unit.

12. The display device of claim 1, wherein the transparency controllable unit surrounds the integrated circuit unit in a top view of the display device.

13. The display device of claim 1, wherein the integrated circuit unit and the at least one light emitting unit are overlapped.

14. The display device of claim 1, wherein the transparency controllable unit surrounds the at least one light emitting unit in a top view of the display device.

15. The display device of claim 1, further comprising an electrode disposed on the substrate and overlapped with the transparency controllable unit, wherein the transparency controllable unit comprises a top electrode, a bottom electrode and a transparency controllable layer between the top electrode and the bottom electrode, and the electrode and one of the top electrode and the bottom electrode are configured to be a capacitor.

16. The display device of claim 1, further comprising a first transistor disposed on the substrate and electrically connected between the at least one light emitting unit and the integrated circuit unit.

17. The display device of claim 16, further comprising a second transistor disposed on the substrate and electrically connected between the transparency controllable unit and the integrated circuit unit.
